(19) United States
(12) Patent Application Publication
(10) Pub. No.: US 2014/0151638 A1
(43) Pub. Date: Jun. 5, 2014

(54) HYBRID NANOMESH STRUCTURES

(71) Applicant: INTERNATIONAL BUSINESS MACHINES CORPORATION, (US)

(72) Inventors: Josephine B. Chang, Mahopac, NY (US); Paul Chang, Mahopac, NY (US); Amlan Majumdar, White Plains, NY (US); Jeffrey W. Sleight, Ridgefield, CT (US)

(73) Assignee: INTERNATIONAL BUSINESS MACHINES CORPORATION, Armonk, NY (US)

(21) Appl. No.: 13/692,182

(22) Filed: Dec. 3, 2012

(51) Int. Cl. H01L 27/088; H01L 21/8232

(52) U.S. Cl. CPC H01L 27/088; H01L 21/8232; Y10S 977/762; B82Y 99/00
USPC 257/27; 438/299

(57) ABSTRACT

An alternating stack of first and second semiconductor layers is formed. Fin-defining mask structures are formed over the alternating stack. A planarization dielectric layer and first and second gate cavities therein are subsequently formed. The first and second gate cavities are extended downward by etching the alternating stack employing a combination of the planarization layer and the fin-defining mask structures as an etch mask. The second semiconductor material is isotropically etched to laterally expand the first gate cavity and to form a first array of semiconductor nanowires including the first semiconductor material, and the first semiconductor material is isotropically etched to laterally expand the second gate cavity and to form a second array of semiconductor nanowires including the second semiconductor material. The first and second gate cavities are filled with replacement gate structures. Each replacement gate structure laterally can surround a two-dimensional array of semiconductor nanowires.

### RELATED APPLICATIONS

The present application is related to co-assigned and co-pending U.S. application Ser. No. ______ (Attorney Docket No: YOR920120671US1; SSMP 29136), which is incorporated herein by reference.

### BACKGROUND

The present disclosure relates to a semiconductor structure, and particularly to hybrid nanomesh structures and a method of manufacturing the same.

Semiconductor materials that provide optimal performance for p-type field effect transistors are different from semiconductor materials that provide optimal performance for n-type field effect transistors. However, integration of p-type field effect transistors and n-type field effect transistors employing different semiconductor materials onto a same substrate in a random pattern is a difficult challenge because two types of semiconductor materials need to be provided in an arbitrary pattern as needed by a circuit layout. This challenge becomes even more difficult when fabrication of three dimensional structures is attempted, which is desirable for the purpose of improving electrostatic control of the gate over the channel and for increasing layout density by decreasing the FET channel footprint.

### BRIEF SUMMARY

An alternating stack of first and second semiconductor layers is formed by alternately depositing a first semiconductor material and a second semiconductor material on a single crystalline substrate layer. Fin-defining mask structures are formed over the alternating stack, and a first disposable gate structure and a second disposable gate structure are subsequently formed. After formation of a planarization dielectric layer, the first and second disposable gate structures are removed to form a first gate cavity and a second gate cavity, respectively. The first and second gate cavities are extended downward by etching the alternating stack employing a combination of the planarization layer and the fin-defining mask structures as an etch mask. Employing masked etch processes, the second semiconductor material is isotropically etched to laterally expand the first gate cavity and to form a first array of semiconductor nanowires including the first semiconductor material, and the first semiconductor material is isotropically etched to laterally expand the second gate cavity and to form a second array of semiconductor nanowires including the second semiconductor material. The first and second gate cavities are filled with replacement gate structures. Each replacement gate structure laterally can surround a two-dimensional array of semiconductor nanowires.

According to an aspect of the present disclosure, a method of forming a semiconductor structure is provided. An alternating stack of a first semiconductor material and a second semiconductor material that is different from the first semiconductor material is formed on a single crystalline substrate layer. A planarization dielectric layer including a first gate cavity and a second gate cavity is formed over the alternating stack. A plurality of first semiconductor nanowires including the first semiconductor material is formed underneath the first gate cavity by patterning a first portion of the alternating stack. A plurality of second semiconductor nanowires including the second semiconductor material is formed underneath the second gate cavity by patterning a second portion of the alternating stack.

According to another aspect of the present disclosure, a semiconductor structure including a first field effect transistor and a second field effect transistor is provided. The first field effect transistor includes a first source region including a first alternating stack of a first semiconductor material and a second semiconductor material that is different from the first semiconductor material, a first drain region including a second alternating stack of the first semiconductor material and the second semiconductor material, a plurality of first channels located within a plurality of first semiconductor nanowires including the first semiconductor material and extending between the first source region and the first drain region, and a first gate electrode surrounding each of the first plurality of semiconductor nanowires. The second field effect transistor includes a second source region including a third alternating stack of the first semiconductor material and the second semiconductor material, a second drain region including a fourth alternating stack of the first semiconductor material and the second semiconductor material, a plurality of second channels located within a plurality of second semiconductor nanowires including the second semiconductor material and extending between the second source region and the second drain region, and a second gate electrode surrounding each of the second plurality of semiconductor nanowires.

### BRIEF DESCRIPTION OF SEVERAL VIEWS OF THE DRAWINGS

FIG. 1A is a top-down view of an exemplary semiconductor structure after formation of an alternating stack of a first semiconductor material and a second semiconductor material on a single crystalline substrate layer according to an embodiment of the present disclosure.

FIG. 1B is a vertical cross-sectional view of the exemplary semiconductor structure along the vertical plane B-B′ of FIG. 1A.

FIG. 2A is a top-down view of the exemplary semiconductor structure after forming of a shallow trench isolation structure according to an embodiment of the present disclosure.

FIG. 2B is a vertical cross-sectional view of the exemplary semiconductor structure along the vertical plane B-B′ of FIG. 2A.

FIG. 3A is a top-down view of the exemplary semiconductor structure after formation of a plurality of fin-defining mask structures according to an embodiment of the present disclosure.

FIG. 3B is a vertical cross-sectional view of the exemplary semiconductor structure along the vertical plane B-B′ of FIG. 3A.

FIG. 4A is a top-down view of the exemplary semiconductor structure after formation of disposable gate structures and source and drain regions according to an embodiment of the present disclosure.

FIG. 4B is a vertical cross-sectional view of the exemplary semiconductor structure along the vertical plane B-B′ of FIG. 4A.

FIG. 5A is a top-down view of the exemplary semiconductor structure after formation of a planarization dielectric layer according to an embodiment of the present disclosure.

FIG. 5B is a vertical cross-sectional view of the exemplary semiconductor structure along the vertical plane B-B′ of FIG. 5A.

FIG. 6A is a top-down view of the exemplary semiconductor structure after removal of the disposable gate structures according to an embodiment of the present disclosure.

FIG. 6B is a vertical cross-sectional view of the exemplary semiconductor structure along the vertical plane B-B′ of FIG. 6A.

FIG. 6C is a vertical cross-sectional view of the exemplary semiconductor structure along the vertical plane C-C′ of FIG. 6A.

FIG. 7A is a top-down view of the exemplary semiconductor structure after vertical extension of gate cavities according to an embodiment of the present disclosure.

FIG. 7B is a vertical cross-sectional view of the exemplary semiconductor structure along the vertical plane B-B′ of FIG. 7A.

FIG. 7C is a vertical cross-sectional view of the exemplary semiconductor structure along the vertical plane C-C′ of FIG. 7A.

FIG. 8A is a top-down view of the exemplary semiconductor structure after removal of physically exposed portions of the plurality of fin-defining mask structures according to an embodiment of the present disclosure.

FIG. 8B is a vertical cross-sectional view of the exemplary semiconductor structure along the vertical plane B-B′ of FIG. 8A.

FIG. 9A is a top-down view of the exemplary semiconductor structure after formation of gate spacers according to an embodiment of the present disclosure.

FIG. 9B is a vertical cross-sectional view of the exemplary semiconductor structure along the vertical plane B-B′ of FIG. 9A.

FIG. 9C is a vertical cross-sectional view of the exemplary semiconductor structure along the vertical plane C-C′ of FIG. 9A.

FIG. 10A is a top-down view of the exemplary semiconductor structure after formation of a first etch-resistant material portion over a second portion of the alternating stack and a lateral etch of physically exposed portions of the second semiconductor material according to an embodiment of the present disclosure.

FIG. 10B is a vertical cross-sectional view of the exemplary semiconductor structure along the vertical plane B-B′ of FIG. 10A.

FIG. 11A is a top-down view of the exemplary semiconductor structure after formation of a second etch-resistant material portion over a first portion of the alternating stack and a lateral etch of physically exposed portions of the first semiconductor material according to an embodiment of the present disclosure.

FIG. 11B is a vertical cross-sectional view of the exemplary semiconductor structure along the vertical plane B-B′ of FIG. 11A.

FIG. 12A is a top-down view of the exemplary semiconductor structure after removal of the second etch-resistant material portion according to an embodiment of the present disclosure.

FIG. 12B is a vertical cross-sectional view of the exemplary semiconductor structure along the vertical plane B-B′ of FIG. 12A.

FIG. 13A is a top-down view of the exemplary semiconductor structure after formation of gate dielectrics and gate electrodes according to an embodiment of the present disclosure.

FIG. 13B is a vertical cross-sectional view of the exemplary semiconductor structure along the vertical plane B-B′ of FIG. 13A.

FIG. 13C is a vertical cross-sectional view of the exemplary semiconductor structure along the vertical plane C-C′ of FIG. 13A.

FIG. 13D is a vertical cross-sectional view of the exemplary semiconductor structure along the vertical plane D-D′ of FIG. 13A.

FIG. 13E is a vertical cross-sectional view of the exemplary semiconductor structure along the vertical plane E-E′ of FIG. 13A.

FIG. 13F is a vertical cross-sectional view of the exemplary semiconductor structure along the vertical plane F-F′ of FIG. 13A.

FIG. 14A is a top-down view of the exemplary semiconductor structure after formation of a contact level dielectric layer and contact via structures therethrough according to an embodiment of the present disclosure.

FIG. 14B is a vertical cross-sectional view of the exemplary semiconductor structure along the vertical plane B-B′ of FIG. 14A.

### DETAILED DESCRIPTION

As stated above, the present disclosure relates to hybrid nanomesh structures and a method of manufacturing the same. Aspects of the present disclosure are now described in detail with accompanying figures. It is noted that like reference numerals refer to like elements across different embodiments. The drawings are not necessarily drawn to scale.

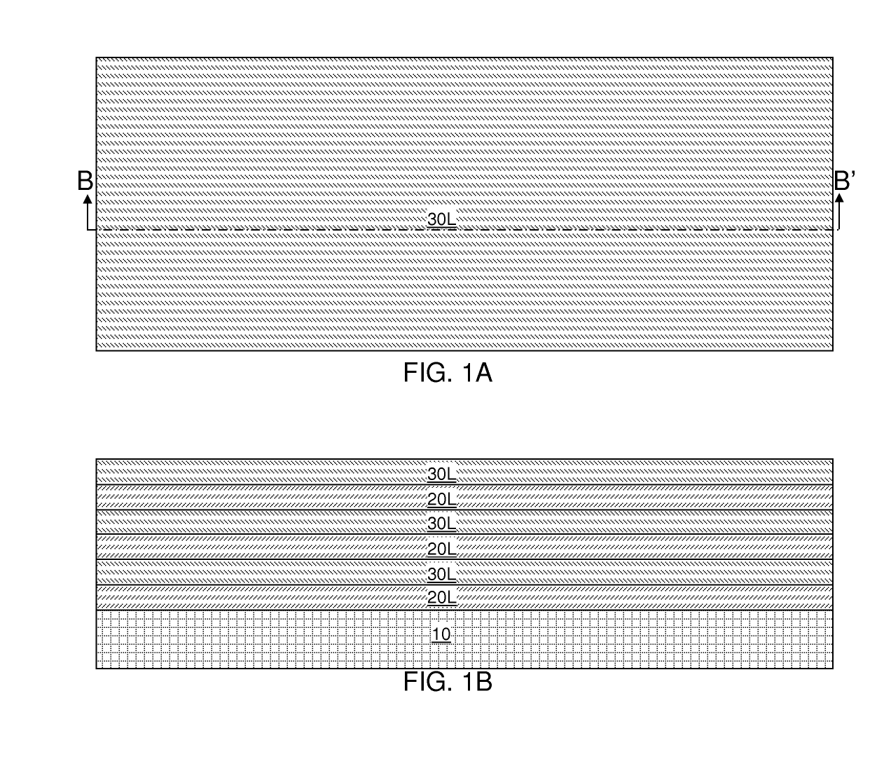

Referring to FIGS. 1A and 1B, an exemplary semiconductor structure according to an embodiment of the present disclosure includes a single crystalline substrate layer 10 and an alternating stack of a first semiconductor material and a second semiconductor material. The single crystalline substrate layer 10 includes a single crystalline semiconductor material. The single crystalline semiconductor material of the single crystalline substrate layer 10 can be a III-V compound semiconductor material or an elemental semiconductor material or an alloy of at least two elemental semiconductors. Exemplary III-V compound semiconductor materials that can be employed for the single crystalline substrate layer 10 include InSb, InP, InN, InGaSb, InGaP, InGaN, InGaAsSb, InGaAsP, InGaAsN, InGaAs, InAsSbP, InAsSb, InAs, InAlAsN, GaSb, GaP, GaN, GaInNAsSb, GaInAsSbP, GaAsSbN, GaAsSb, GaAsP, GaAsN, GaAs, BP, BN, BN, BAs, AlSb, AlP, AlN, AlInSb, AlInAsP, AlInAs, AlGaP, AlGaN, AlGaInP, AlGaAsP, AlGaAsN, AlGaAs, and AlAs. Exemplary elemental semiconductor materials that can be employed for the single crystalline substrate layer 10 include silicon, germanium, a silicon-germanium alloy, a silicon-carbon alloy, and a silicon-germanium-carbon alloy. The single crystalline substrate layer 10 can have a planar top surface. In one embodiment, the single crystalline substrate layer 10 can be an intrinsic semiconductor material layer so as to minimize a leakage current in field effect transistors to be subsequently formed.

The first semiconductor material is deposited as single crystalline semiconductor material layers in epitaxial alignment with the singe crystalline substrate layer 10. Each layer including the first semiconductor material is herein referred to as a first semiconductor material layer 20L, which is a single crystalline semiconductor material layer. The second semiconductor material is different in composition from the first semiconductor material. The second semiconductor material is deposited as single crystalline semiconductor material layers in epitaxial alignment with the singe crystalline substrate layer 10. Each layer including the second semiconductor material is herein referred to as a second semiconductor material layer 30L, which is a single crystalline semiconductor material layer. Thus, the entirety of the alternating stack (20L, 30L) is epitaxially aligned to the single crystalline substrate layer upon formation.

Specifically, each first semiconductor material layer 20L can be deposited directly on the top surface of an underlying single crystalline material layer, which can be the single crystalline substrate layer 10 or one of the second semiconductor material layers 30L. Each first semiconductor material layer 20L is epitaxially aligned to the underlying single crystalline material layer. The first semiconductor material of the first semiconductor material layers 20L is different from the semiconductor material of the single crystalline substrate layer 10. Each second semiconductor material layer 30L can be deposited directly on the top surface of an underlying single crystalline material layer, which can be one of the second semiconductor material layers 30L. Each second semiconductor material layer 30L is epitaxially aligned to the underlying single crystalline material layer.

Each of the first semiconductor material and the second semiconductor material can be independently selected from a III-V compound semiconductor material, which can be one of InSb, InP, InN, InGaSb, InGaP, InGaN, InGaAsSb, InGaAsP, InGaAsN, InGaAs, InAsSbP, InAsSb, InAs, InAlAsN, GaSb, GaP, GaN, GaInNAsSb, GaInAsSbP, GaAsSbN, GaAsSb, GaAsP, GaAsN, GaAs, BP, BN, BN, BAs, AlSb, AlP, AlN, AlInSb, AlInAsP, AlInAs, AlGaP, AlGaN, AlGaInP, AlGaAsP, AlGaAsN, AlGaAs, and AlAs. Alternatively, each of the first semiconductor material and the second semiconductor material can be independently selected from elemental semiconductor materials, which include silicon, germanium, a silicon-germanium alloy, a silicon-carbon alloy, and a silicon-germanium-carbon alloy. Yet alternately, one of the first semiconductor material and the second semiconductor material can be a III-V compound semiconductor material, and the other of the first semiconductor material and the second semiconductor material can be an elemental semiconductor material or an alloy of at least two elemental semiconductor materials. As used herein, an elemental semiconductor material refers to silicon, germanium, and carbon.

In one embodiment, one of the first semiconductor material and the second semiconductor material can have a lattice constant that is greater than the lattice constant of the single crystalline substrate layer 10, and another of the first semiconductor material and the second semiconductor material has another lattice constant that is less than the lattice constant of the single crystalline substrate layer 10. In one embodiment, one of the first semiconductor material and the second semiconductor material can include a III-V compound semiconductor material having a lattice constant that is greater than the lattice constant of the single crystalline substrate layer 10, and another of the first semiconductor material and the second semiconductor material can include an elemental semiconductor material or an alloy of at least two elemental semiconductor materials that has another lattice constant that is less than the lattice constant of the single crystalline substrate layer 10. In another embodiment, one of the first semiconductor material and the second semiconductor material can include a III-V compound semiconductor material having a lattice constant that is less than the lattice constant of the single crystalline substrate layer 10, and another of the first semiconductor material and the second semiconductor material can include an elemental semiconductor material or an alloy of at least two elemental semiconductor materials that has another lattice constant that is greater than the lattice constant of the single crystalline substrate layer 10.

One of the first and second semiconductor materials having a lattice constant that is greater than the lattice constant of the single crystalline substrate layer 10 is under a biaxial stress, and the other of the first and second semiconductor materials having a lattice constant that is less than the lattice constant of the single crystalline substrate layer 10 is under a tensile stress.

The thicknesses of the first semiconductor material layers 20L and the second semiconductor material layers 30L are selected such that the entirety of the epitaxial alignment of the first semiconductor material layers 20L and the second semiconductor material layers 30L can be maintained throughout the entirety of the alternating stack (20L, 30L). Thus, the thickness of each of the first semiconductor material layers 20L and the second semiconductor material layers 30L is less than the critical thickness, which is the thickness at which an epitaxial material begins to lose epitaxial registry with the underlying single crystalline layer by developing dislocations.

In one embodiment, the first and second semiconductor materials can be selected such that the thicknesses of each first semiconductor material layer 20L and each second semiconductor material layer 30L can be in a range from 3 nm to 60 nm, although lesser and greater thicknesses can also be employed. In one embodiment, the thickness of the first semiconductor material layers 20L can be the same. In this case, the thicknesses of each first semiconductor material layer 20L is herein referred to as a first thickness. Additionally or alternatively, the thicknesses of the second semiconductor material layers 30L can be the same. In this case, the thickness of each second semiconductor material layer 30L is herein referred to as a second thickness.

The number of repetitions for a pair of a first semiconductor material layer 20L and a second semiconductor material layer 30L can be 2 or greater. In one embodiment, the number of repetitions for a pair of a first semiconductor material layer 20L and a second semiconductor material layer 30L can be in a range from, and including, 2 to, and including, 30. The alternating stack may terminate with a second semiconductor material layer 30L or with a first semiconductor material layer 20L.

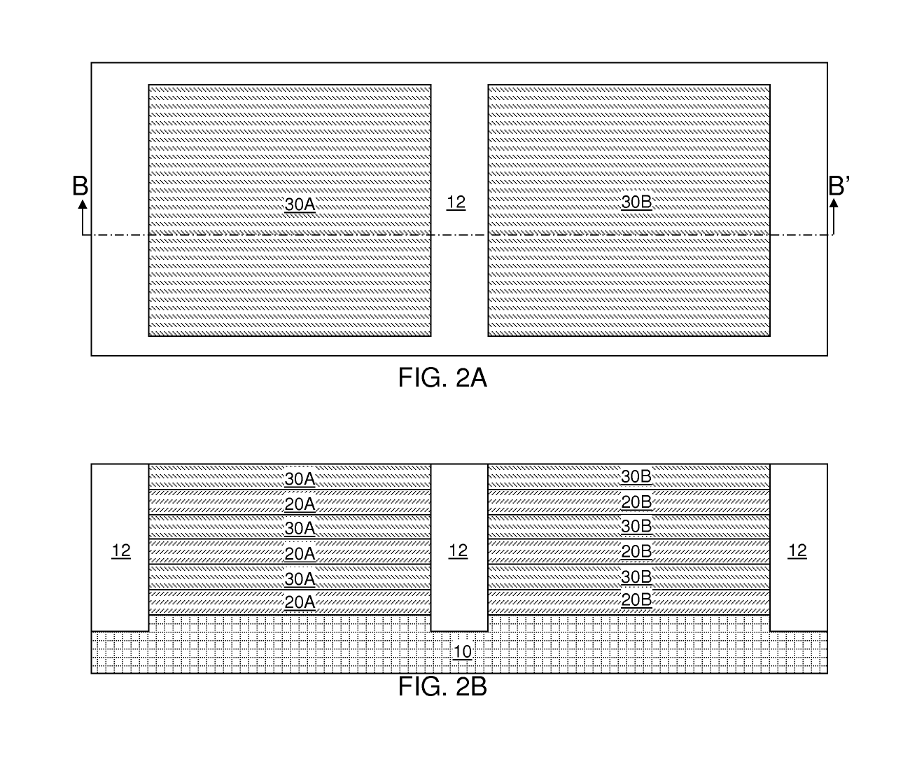

Referring to FIGS. 2A and 2B, a shallow trench isolation structure 12 including a dielectric material can be formed. Specifically, a shallow trench laterally enclosing at least one portion of the alternating stack (20L, 30L) can be formed by applying a photoresist layer (not shown) over the alternating stack (20L, 30L), by lithographically patterning the photoresist layer, and by transferring the pattern through the alternating stack (20L, 30L) and an upper portion of the single crystalline substrate layer 10L by an etch. The etch can be an anisotropic etch or an isotropic etch. The photoresist layer is subsequently removed, for example, by ashing.

At least one dielectric material such as silicon oxide, silicon nitride, and/or silicon oxynitride is deposited into the shallow trench. Excess dielectric material is removed from above the topmost surface of the remaining portion of the alternating stack (20L, 30L), for example, by chemical mechanical planarization (CMP). The remaining portions of the at least one dielectric material within the shallow trench constitute the shallow trench isolation structure 12.

In one embodiment, the shallow trench isolation structure 12 can laterally surround a first alternating stack of a first subset of remaining portions of the first semiconductor material layer 20L and a first subset of remaining portions of the second semiconductor material layer 30L. The first subset of remaining portions of the first semiconductor material layer 20L and the first subset of remaining portions of the second semiconductor material layer 30L can be doped with dopants of a first conductivity type prior to, or after, formation of the shallow trench isolation structure 12. The first conductivity type can be p-type or n-type.

The doping of the first subset of remaining portions of the first semiconductor material layer 20L and the first subset of remaining portions of the second semiconductor material layer 30L can be performed by providing a dopant of the first conductivity type to a first portion of the alternating stack (20L, 30L) that includes the first alternating stack. In this case, the first subset of remaining portions of the first semiconductor material layer 20L having a doping of the first conductivity type is referred to as first-conductivity-type first semiconductor material layers 20A, and the first subset of remaining portions of the second semiconductor material layer 30L having a doping of the first conductivity type is herein referred to as first-conductivity-type second semiconductor material layers 30A. The first alternating stack (20A, 30A) includes the first-conductivity-type first semiconductor material layers 20A and the first-conductivity-type second semiconductor material layers 30A.

Further, the shallow trench isolation structure 12 can laterally surround a second alternating stack of a second subset of remaining portions of the first semiconductor material layer 20L and a second subset of remaining portions of the second semiconductor material layer 30L. The second subset of remaining portions of the first semiconductor material layer 20L and the second subset of remaining portions of the second semiconductor material layer 30L can be doped with dopants of a second conductivity type prior to, or after, formation of the shallow trench isolation structure 12. The second conductivity type is the opposite type of the first conductivity type. For example, if the first conductivity type is p-type, the second conductivity type is n-type, and vice versa.

The doping of the second subset of remaining portions of the first semiconductor material layer 20L and the second subset of remaining portions of the second semiconductor material layer 30L can be performed by providing a dopant of the second conductivity type to a second portion of the alternating stack (20L, 30L) that includes the second alternating stack. In this case, the second subset of remaining portions of the first semiconductor material layer 20L having a dopant of the second conductivity type is referred to as second-conductivity-type first semiconductor material layers 20B, and the second subset of remaining portions of the second semiconductor material layer 30L having a doping of the second conductivity type is herein referred to as second-conductivity-type second semiconductor material layers 30B. The second alternating stack (20B, 30B) includes the second-conductivity-type first semiconductor material layers 20B and the second-conductivity-type second semiconductor material layers 30B.

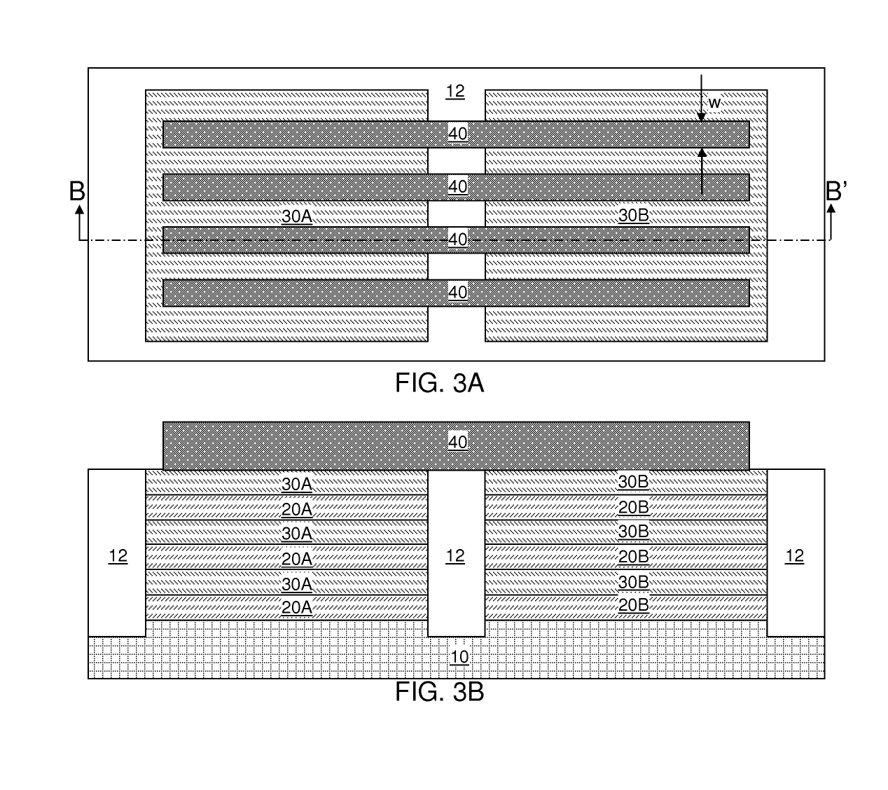

Referring to FIGS. 3A and 3B, an optional etch stop layer can be formed over the topmost surfaces of first alternating stack (20A, 20B) and the second alternating stack (20B, 30B). The optional etch stop layer, if present, can be subsequently employed as a stopping layer for an etch process. A plurality of fin-defining mask structures 40 is formed over the first alternating stack (20A, 30A) and the second alternating stack (20B, 30B). The plurality of fin-defining mask structures 40 can be mask structures that cover the regions of the first alternating stack (20A, 30A) and the second alternating stack (20B, 30B) in which field effect transistors are subsequently formed.

The plurality of fin-defining mask structures 40 can be formed, for example, by depositing a planar dielectric material layer and lithographically patterning the dielectric material layer. The planar dielectric material layer can be deposited, for example, by chemical vapor deposition (CVD). The planar dielectric material layer can include a dielectric material such as silicon nitride, silicon oxide, silicon oxynitride, a dielectric metal oxide, a dielectric metal nitride, or a dielectric metal oxynitride. The thickness of the planar dielectric material layer can be from 5 nm to 300 nm, although lesser and greater thicknesses can also be employed. The planar dielectric material layer can be subsequently patterned to form the plurality of fin-defining mask structures 40.

In one embodiment, each fin-defining mask structure 40 in the plurality of fin-defining mask structures 40 can laterally extend along a lengthwise direction. Further, each fin-defining mask structure 40 in the plurality of fin-defining mask structures 40 can have a pair of sidewalls that are separated along a widthwise direction, which is perpendicular to the lengthwise direction. In one embodiment, each fin-defining mask structure 40 in the plurality of fin-defining mask structures 40 can have a rectangular horizontal cross-sectional area. In one embodiment, the fin-defining mask structures 40 in the plurality of fin-defining mask structures 40 can have the same width w.

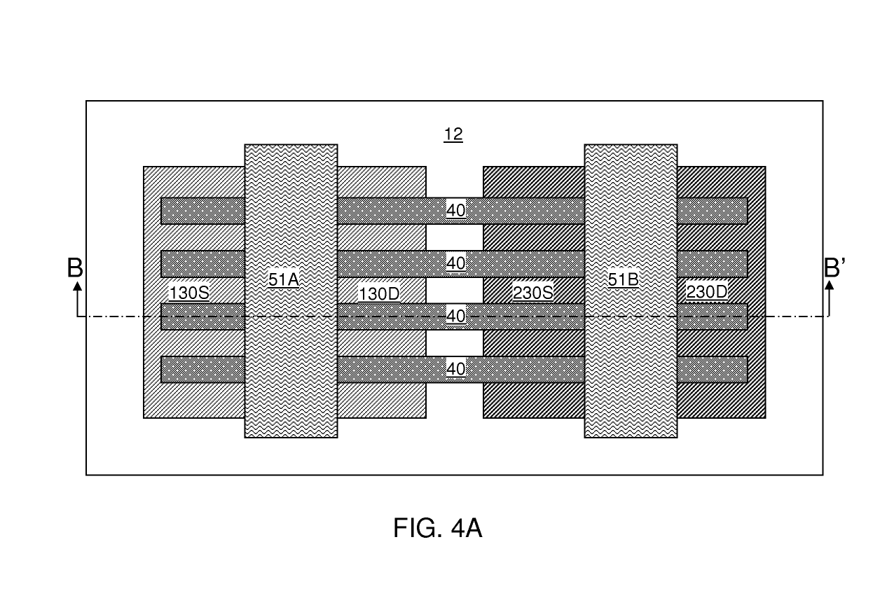

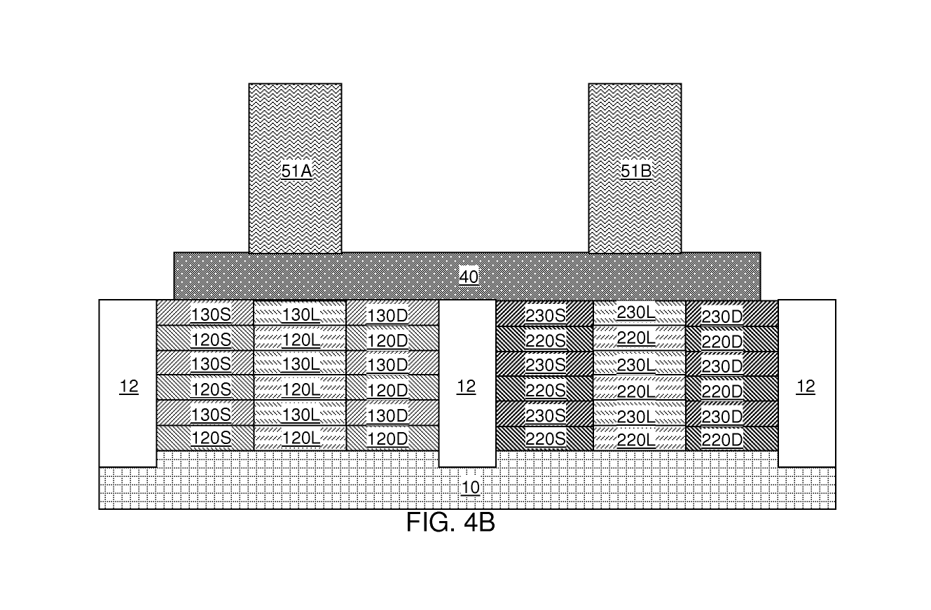

Referring to FIGS. 4A and 4B, disposable gate structures (51A, 51B) can be formed, for example, by depositing a disposable gate material layer (not shown), and subsequently lithographically patterning the disposable gate material layer. Remaining portions of the disposable gate material layer after the lithographic patterning constitute the disposable gate structures (51A, 51B).

The disposable gate material layer includes a material that can be removed selective to the material of the plurality of fin-defining mask structures 40. In this case, the disposable gate material layer can include a dielectric material or a metallic material. The disposable gate material layer can be deposited, for example, by chemical vapor deposition (CVD). The thickness of the disposable gate material layer, as measured above a planar surface, can be from 50 nm to 600 nm, although lesser and greater thicknesses can also be employed.

A photoresist layer (not shown) can be applied over the disposable gate material layer. The photoresist layer can be subsequently patterned into gate patterns, which are typically a plurality of lines which run perpendicular to and intersect the plurality of fin-defining mask structures 40. Physically exposed portions of the disposable gate material layer, i.e., portions of the disposable gate material layer that are not covered by the patterned photoresist layer, are removed, for example, by an etch, which can be an anisotropic etch. The etch that removes physically exposed portions of the disposable gate material layer can be selective to the materials of the plurality of fin-defining mask structures 40 and selective to the material of the topmost semiconductor layers, which can be second semiconductor material layers (30A, 30B) or first semiconductor material layers (20A, 20B).

If the optional etch stop layer is present, the etch that removes physically exposed portions of the disposable gate material layer can be selective to the materials of the optional etch stop layer. If the optional dielectric pad layer 40L is not present, the etch that removes physically exposed portions of the disposable gate material layer can be selective to the topmost semiconductor material of the first alternating stack (20A, 30A) and the second alternating stack (20B, 30B). The disposable gate structures 51 straddles over middle portions of the plurality of fin-defining mask structures 40.

Source and drain regions can be formed by implanting dopants into the first alternating stack (20A, 30A) and the second alternating stack (20B, 30B) employing the disposable gate structures (51A, 51B) as self-aligned masking structures. The disposable gate structures (51A, 51B) include a first disposable gate structure 51A formed over the first alternating stack (20A, 30A) (which is a first portion of the alternating stack (20L, 30L)) and a second disposable gate structure 51B formed over the second alternating stack (20B, 30B) (which is a second portion of the alternating stack (20L, 30L).

Sub-portions of the first alternating stack (20A, 30A) that are not masked with the first disposable gate structure 51A are implanted with dopants of the second conductivity type to form a first source region (120S, 130S) and a first drain region (120D, 130D). The first disposable gate structure 51A is employed as an implantation mask during the ion implantation that forms the first source region (120S, 130S) and the first drain region (120D, 130D). The second alternating stack (20B, 30B) can be masked within a patterned masking layer (which can be a patterned photoresist layer) during the ion implantation that forms the first source region (120S, 130S) and the first drain region (120D, 130D).

The first source region (120S, 130S) includes an alternating stack of first material first source regions 120S and second material first source regions 130S. The first source region (120S, 130S) is a first subset of the alternating stack (20L, 30L; See FIG. 1B). The first drain region (120D, 130D) includes an alternating stack of first material first drain regions 120D and second material first drain regions 130D. The first drain region (120D, 130D) is a second subset of the alternating stack (20L, 30L; See FIG. 1B).

The first source region (120S, 130S) and the first drain region (120D, 130D) have a doping of the second conductivity type. The portions of the first alternating stack (20A, 30A) that are not doped with dopants of the second conductivity type, and thus, have a doping of the first conductivity type, include a vertical stack of first material first conductivity type layers 120L and second material first conductivity type layers 130L. Each first material first conductivity type layer 120L includes the first semiconductor material and has a doping of the first conductivity type, and each second material first conductivity type layer 130L includes the second semiconductor material and has a doping of the first conductivity type. A junction is formed between the first source region (120S, 130S) and the vertical stack of first material first conductivity type layers 120L and second material first conductivity type layers 130L. Another junction is formed between the first drain region (120D, 130D) and the vertical stack of first material first conductivity type layers 120L and second material first conductivity type layers 130L. In one embodiment, the junctions can be p-n junctions. In another embodiment, the vertical stack of first material first conductivity type layers 120L and second material first conductivity type layers 130L can include intrinsic semiconductor materials, and the junctions can be between doped semiconductor materials and intrinsic semiconductor materials.

Sub-portions of the second alternating stack (20B, 30B) that are not masked with the second disposable gate structure 51B are implanted with dopants of the first conductivity type to form a second source region (220S, 230S) and a second drain region (220D, 230D). The second disposable gate structure 51B is employed as an implantation mask during the ion implantation that forms the second source region (220S, 230S) and the second drain region (220D, 230D). The first alternating stack (20A, 30A) can be masked within a patterned masking layer (which can be a patterned photoresist layer) during the ion implantation that forms the second source region (220S, 230S) and the second drain region (220D, 230D).

The second source region (220S, 230S) includes an alternating stack of first material second source regions 220S and second material second source regions 230S. The second source region (220S, 230S) is a third subset of the alternating stack (20L, 30L; See FIG. 1B). The second drain region (220D, 230D) includes an alternating stack of first material second drain regions 220D and second material second drain regions 230D. The second drain region (220D, 230D) is a fourth subset of the alternating stack (20L, 30L; See FIG. 1B).

The second source region (220S, 230S) and the second drain region (220D, 230D) have a doping of the first conductivity type. The portions of the second alternating stack (20B, 30B) that are not doped with dopants of the first conductivity type, and thus, have a doping of the second conductivity type, include a vertical stack of first material second conductivity type layers 220L and second material second conductivity type layers 230L. Each first material second conductivity type layer 220L includes the first semiconductor material and has a doping of the second conductivity type, and each second material second conductivity type layer 230L includes the second semiconductor material and has a doping of the second conductivity type. A junction is formed between the second source region (220S, 230S) and the vertical stack of first material second conductivity type layers 220L and second material second conductivity type layers 230L. Another junction is formed between the second drain region (220D, 230D) and the vertical stack of first material second conductivity type layers 220L and second material second conductivity type layers 230L. In one embodiment, the junctions can be p-n junctions. In another embodiment, the vertical stack of first material first conductivity type layers 120L and second material first conductivity type layers 130L can include intrinsic semiconductor materials, and the junctions can be between doped semiconductor materials and intrinsic semiconductor materials.

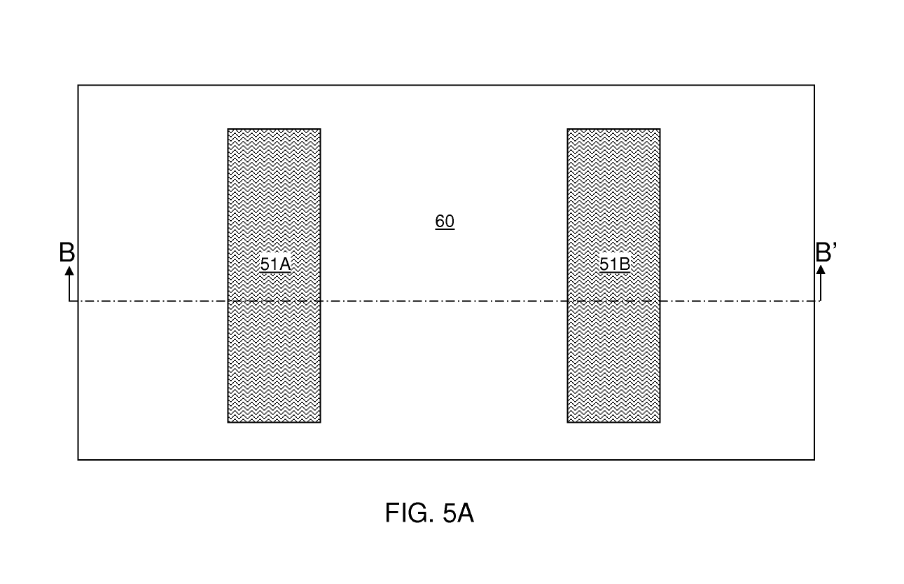

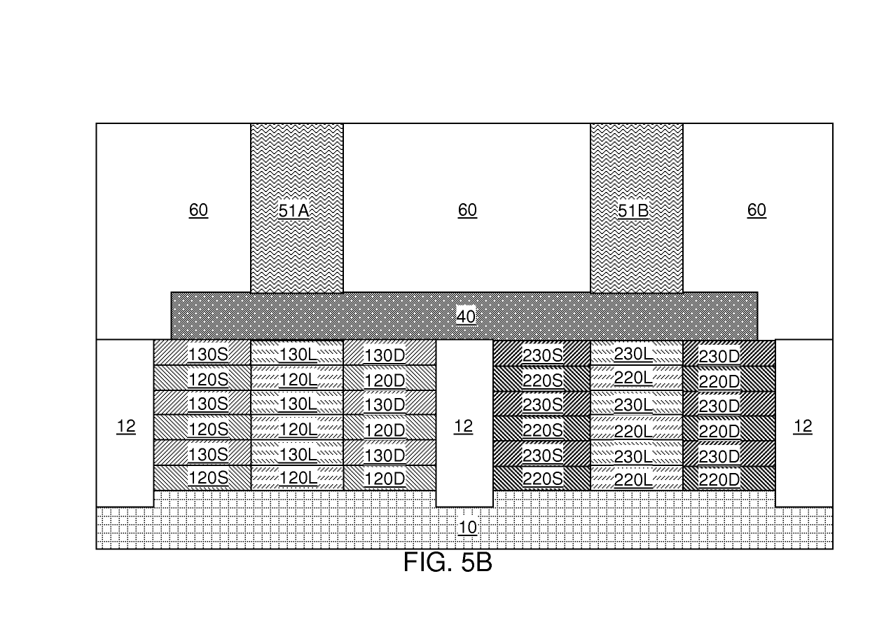

Referring to FIGS. 5A and 5B, a planarization dielectric layer 60 is formed over the first and second alternating stacks and the plurality of fin-defining mask structures 40. The planarization dielectric layer 60 can be formed, for example, by depositing a dielectric material over the first and second alternating stacks, the plurality of fin-defining mask structures 40, and the first and second disposable gate structures (51A, 51B), and subsequently planarizing the dielectric material to form a planar top surface that is coplanar with the top surfaces of remaining portions of the first and second disposable gate structures (51A, 51B). Alternately, the planarization dielectric layer 60 can include a self-planarizing dielectric material. In this case, the deposition and planarization of the dielectric material for formation of the planarization dielectric layer 60 can be performed simultaneously. The dielectric material of the planarization dielectric layer 60 can include, for example, silicon oxide, silicon nitride, silicon oxynitride, organosilicate glass, and/or a spin-on dielectric material.

Because of the presence of the first and second disposable gate structures (51A, 51B), the planarization dielectric layer 60 includes a first hole corresponding to the volume of the first disposable gate structure 51A and a second hole corresponding to the volume of the second disposable gate structure 51B.

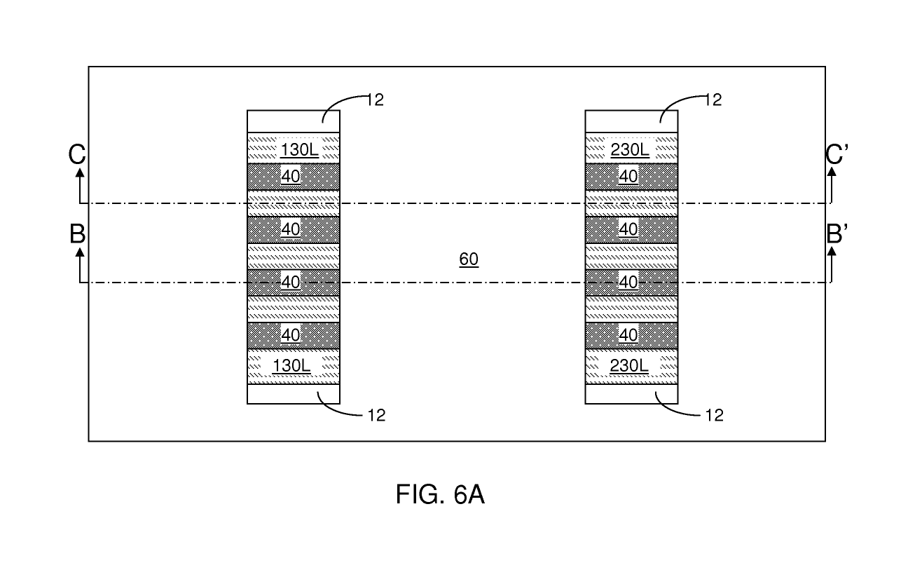

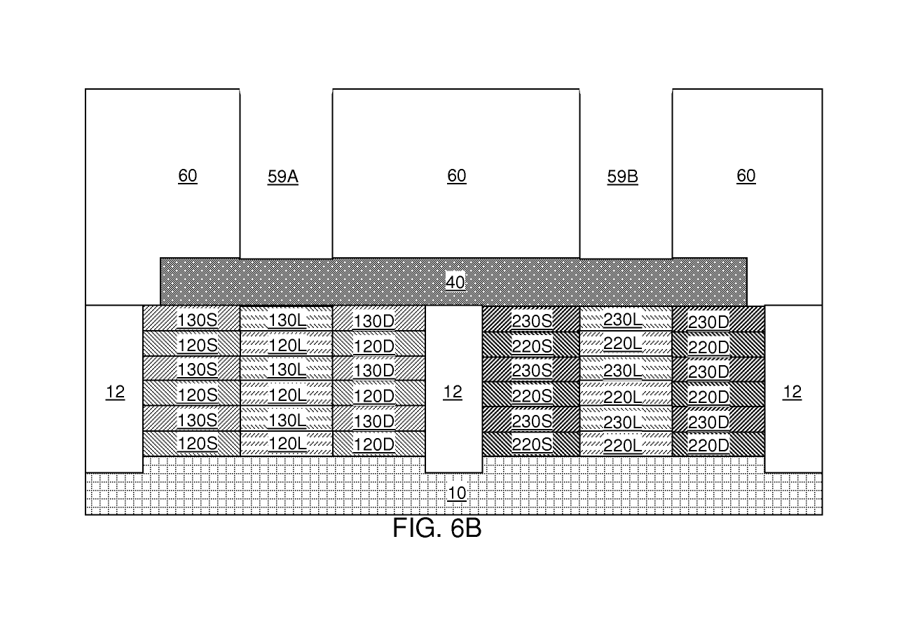

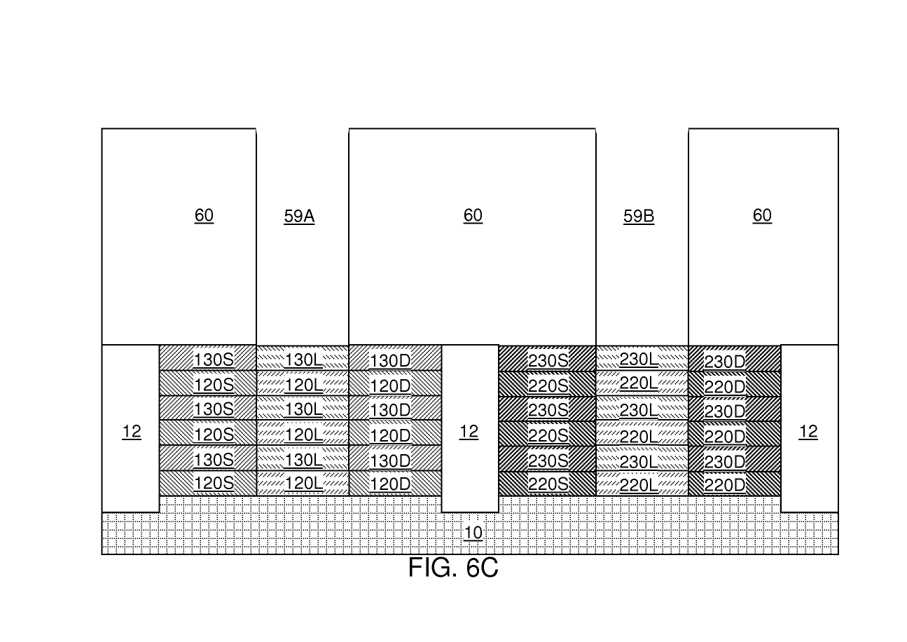

Referring to FIGS. 6A, 6B, and 6C, the first and second disposable gate structures (51A, 51B) are removed selective to the planarization dielectric layer 60 and the topmost semiconductor material in the first and second alternating stack. A first gate cavity 59A is formed in the volume from which the first disposable gate structure 51A is removed, and a second gate cavity 59B is formed in the volume from which the second disposable gate structure 51B is removed. The planarization dielectric layer 60 includes a first gate cavity 59A and a second gate cavity 59B that are located over the first alternating stack and over the second alternating stack, respectively.

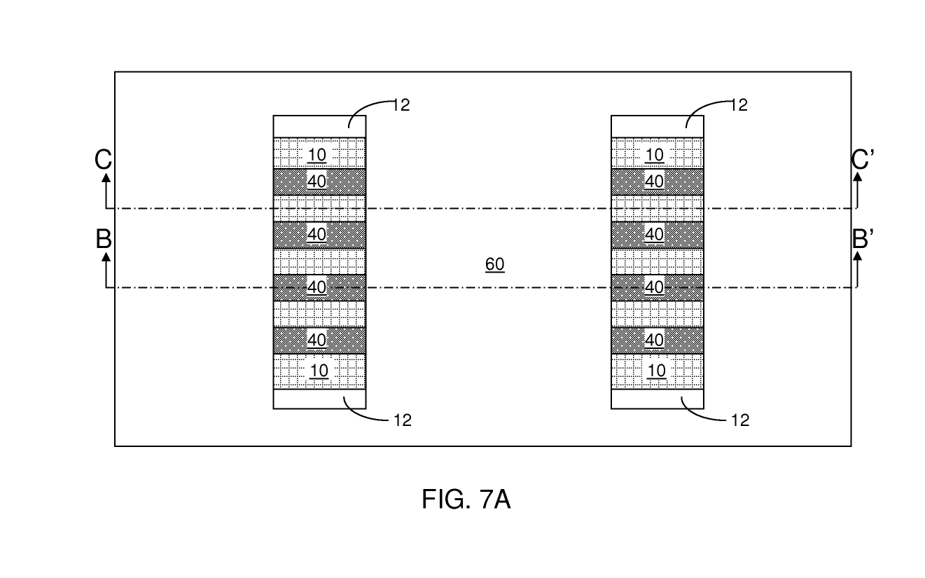

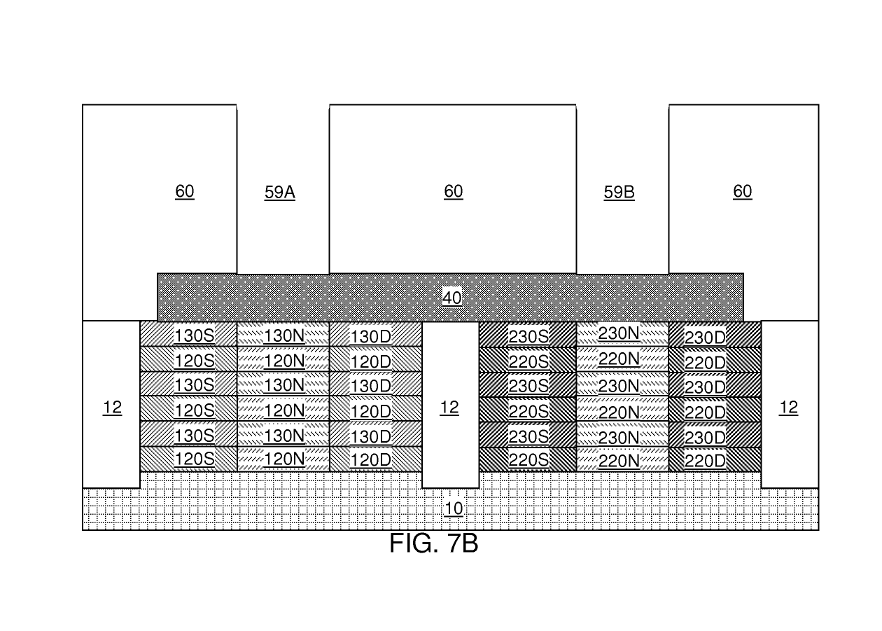

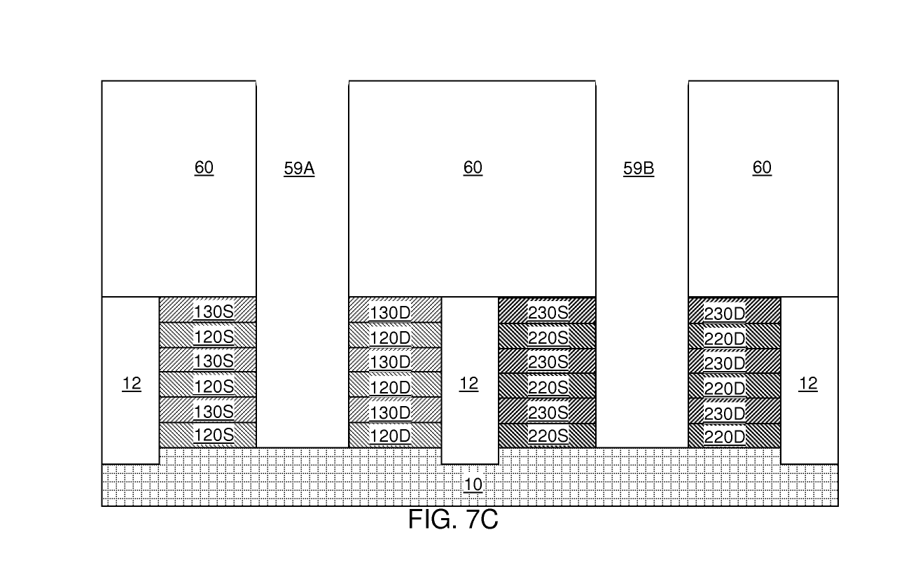

Referring to FIGS. 7A, 7B, and 7C, the first and second gate cavities (59A, 59B) are vertically extended downward by anisotropically etching the first and second alternating stacks employing the combination of the planarization dielectric layer 60 and the plurality of fin-defining mask structures 40 as an etch mask. Thus, the first gate cavity 59A and the second gate cavity 59B are vertically extended only within regions that are not blocked by the plurality of fin-defining mask structures 40. The first gate cavity 59A can be vertically extended downward at least to the top surface of the single crystalline substrate layer 10. Likewise, the second gate cavity 59B can be vertically extended downward to the top surface of the single crystalline substrate layer 10.

The remaining portions of the vertical stack of first material first conductivity type layers 120L and second material first conductivity type layers 130L form a plurality of first vertical stacks of nanowires (120N, 130N). As used herein, a “nanowire” refers to a structure having lateral dimensions not exceeding 100 nm and extending along a lengthwise direction for a distance greater than any widthwise dimension. Each first vertical stack of nanowires (120N, 130N) includes first material first conductivity type nanowires 120N and second material first conductivity type nanowires 130N. Each first material first conductivity type nanowire 120N includes the first semiconductor material and has a doping of the first conductivity type, and each second material first conductivity type nanowire 130N includes the second semiconductor material and has a doping of the first conductivity type. A junction is present between the first source region (120S, 130S) and each first vertical stack of nanowires (120N, 130N). Another junction is formed between the first drain region (120D, 130D) and each first vertical stack of nanowires (120N, 130N). In one embodiment, the junctions can be p-n junctions. In another embodiment, the junctions can be between doped semiconductor materials and intrinsic semiconductor materials.

The remaining portions of the vertical stack of first material second conductivity type layers 220L and second material second conductivity type layers 230L form a plurality of second vertical stacks of nanowires (220N, 230N). Each second vertical stack of nanowires (220N, 230N) includes first material second conductivity type nanowires 220N and second material second conductivity type nanowires 230N. Each first material second conductivity type nanowire 220N includes the first semiconductor material and has a doping of the second conductivity type, and each second material second conductivity type nanowire 230N includes the second semiconductor material and has a doping of the second conductivity type. A junction is present between the second source region (220S, 230S) and each second vertical stack of nanowires (220N, 230N). Another junction is formed between the second drain region (220D, 230D) and each second vertical stack of nanowires (220N, 230N). In one embodiment, the junctions can be p-n junctions. In another embodiment, the junctions can be between doped semiconductor materials and intrinsic semiconductor materials.

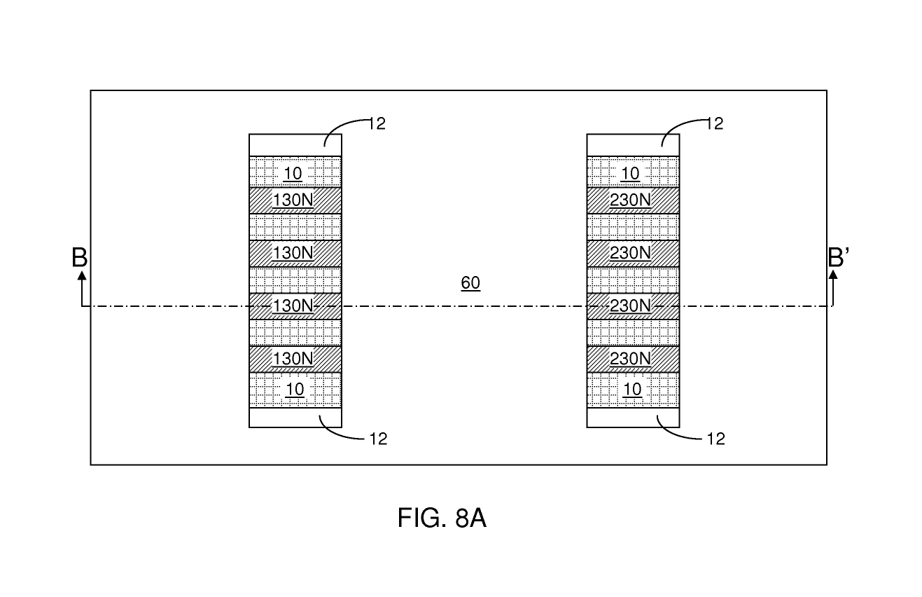

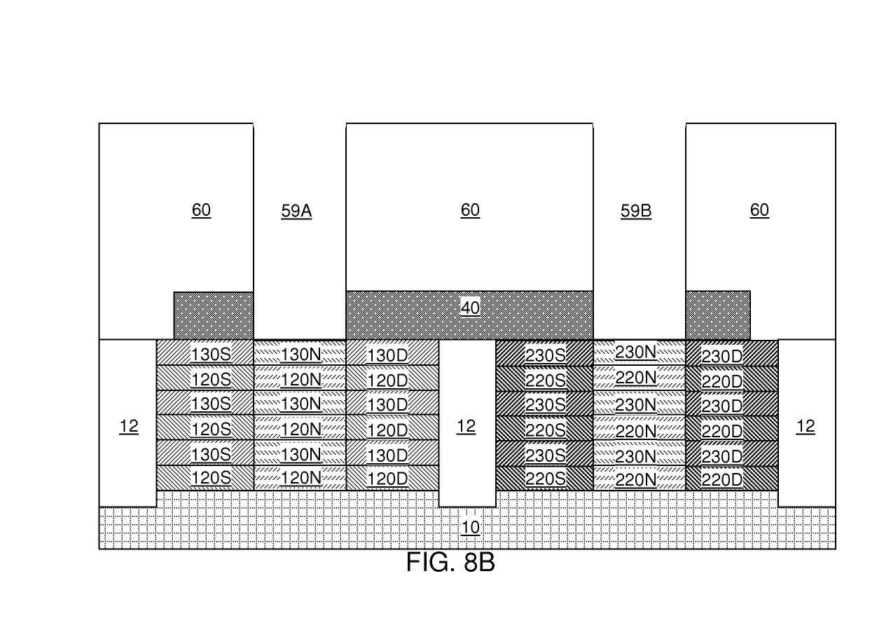

Referring to FIGS. 8A and 8B, physically exposed portions of the plurality of fin-defining mask structures 40 can be optionally removed by an etch, which can be an isotropic etch or an anisotropic etch. The removal of the physically exposed portions of the plurality of fin-defining mask structures 40 is performed selective to the plurality of first vertical stacks of nanowires (120N, 130N) and the plurality of second vertical stacks of nanowires (220N, 230N). For example, if the plurality of fin-defining mask structures 40 include silicon nitride, the removal of the physically exposed portions of the plurality of fin-defining mask structures 40 can be performed by a wet etch employing hot phosphoric acid.

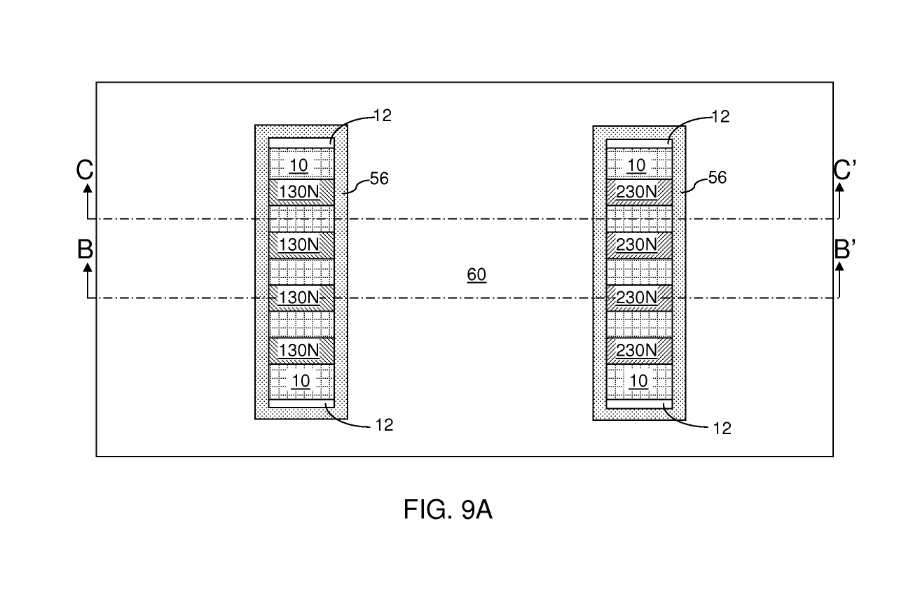

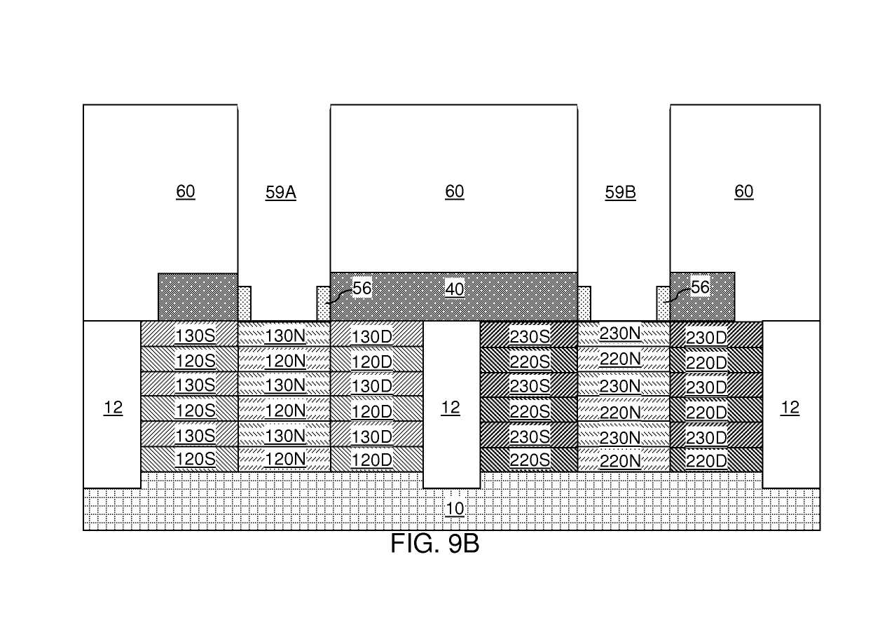

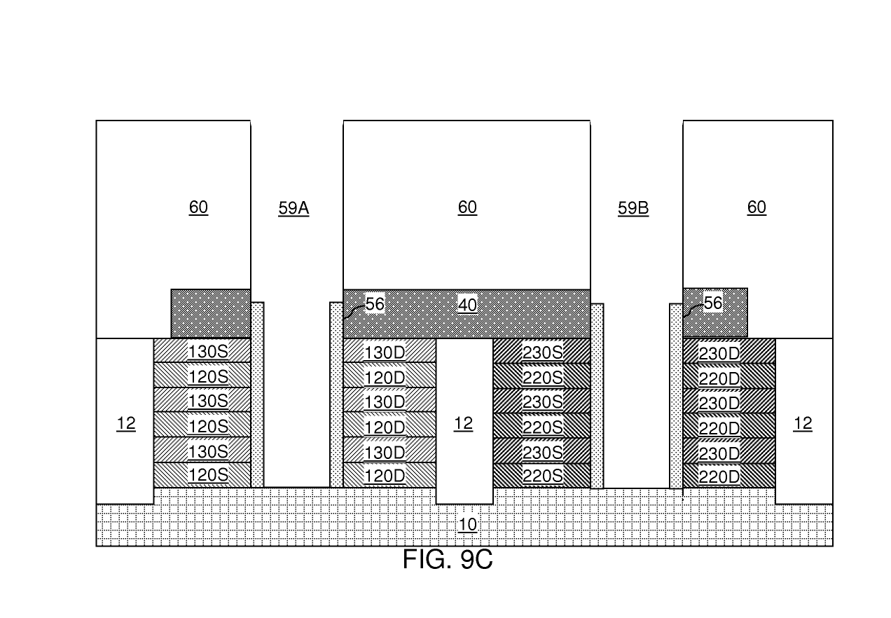

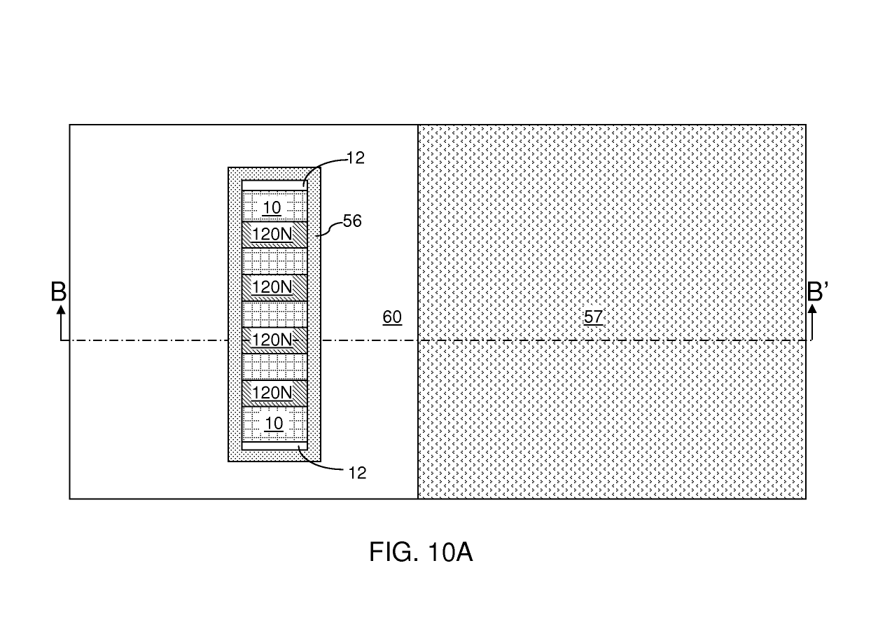

Referring to FIGS. 9A, 9B, and 9C, gate spacers 56 can be formed on sidewalls of the planarization dielectric layer 60 within the first and second gate cavities (59A, 59B). A conformal dielectric material layer (not shown) can be deposited, for example, by chemical vapor deposition (CVD) or atomic layer deposition (ALD). The conformal dielectric material layer includes a dielectric material such as silicon nitride, silicon oxide, a dielectric metal oxide, or a combination thereof. The thickness of the conformal dielectric material layer can be from 3 nm to 100 nm, although lesser and greater thicknesses can also be employed.

The dielectric material of the conformal dielectric material layer may, or may not be, the same as the dielectric material of the plurality of fin-defining mask structures 40. In one embodiment, the dielectric material of the conformal dielectric material layer can be the same as the dielectric material of the plurality of fin-defining mask structures 40. In one embodiment, the dielectric material of the conformal dielectric material layer and the dielectric material of the plurality of fin-defining mask structures 40 can be silicon nitride. Vertical portions of the conformal dielectric material layer are subsequently etched by an anisotropic etch to form the gate spacers 56.

A first gate spacer (56 in the left side) including a dielectric material can be formed on the sidewalls of the planarization dielectric layer 60 and sidewalls of remaining portions of the plurality of fin-defining mask structures 40 that are present within the vertically extended first gate cavity 59A. A second gate spacer (56 in the right side) including the dielectric material can be formed on the sidewall of the planarization dielectric layer 60 and sidewalls of remaining portions of the plurality of fin-defining mask structures 40 that are present within the vertically extended second gate cavity 59B. Each of the first and second gate spacers 56 can include at least one vertical strip having a uniform width as illustrated in FIG. 9C. The uniform width is the same as the spacing between a neighboring pair of first vertical stacks of nanowires (120N, 130N) or a neighboring pair of second vertical stacks of nanowires (220N, 230N).

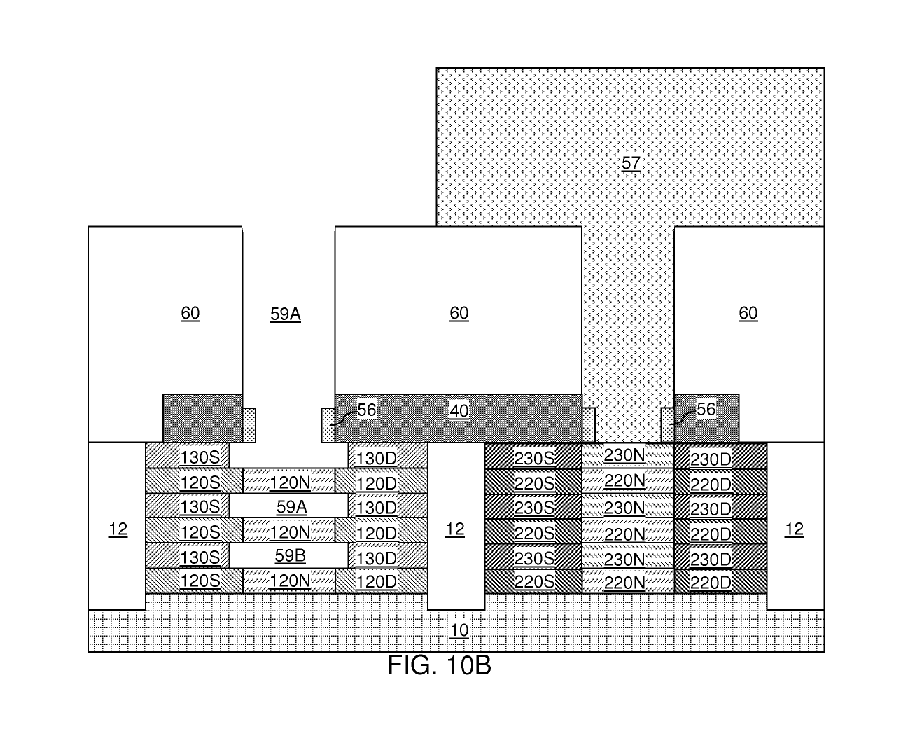

Referring to FIGS. 10A and 10B, a first etch-resistant material portion 57 is formed over the second alternating stack (220S, 230S, 220N, 230N, 220S, 230D), which is a second portion of the alternating stack (20L, 30L; See FIG. 1B). The first etch-resistant material portion 57 is a masking structure that prevents etching of materials in the second alternating stack (220S, 230S, 220N, 230N, 220S, 230D). In one embodiment, the first etch-resistant material portion 57 can be a patterned photoresist material portion, which can be formed by applying a photoresist material over the planarization dielectric layer 60 and within the first and second gate cavities (59A, 59B), and lithographically patterning the photoresist material such that the remaining photoresist material is present over the second alternating stack (220S, 230S, 220N, 230N, 220S, 230D), and is not present over the first alternating stack (120S, 130S, 120N, 130N, 120S, 130D).

A lateral etch of physically exposed portions of the second semiconductor material is performed selective to the first semiconductor material. An isotropic wet etch or an isotropic dry etch can be employed for the lateral etch. Thus, the first gate cavity 59A is laterally expanded by removing the second semiconductor material selective to the first semiconductor material while the first etch-resistant material portion 57 masks the second alternating stack (220S, 230S, 220N, 230N, 220S, 230D). The second material first conductivity type nanowires 130N and physically exposed end sub-portions of the second material first source portions 130S and the second material first drain portions 130D are removed by the lateral etch. The first material first conductivity type nanowires 120N become suspended or contact the single crystalline substrate layer 10. The first material first conductivity type nanowires 120N constitute a plurality of first suspended semiconductor nanowires, and includes the first semiconductor material, and are located underneath the first gate cavity 59A as formed at the processing step of FIGS. 6A, 6B, and 6C.

The etch chemistry for the isotropic selective etch can be optimized for the combination of the first semiconductor material and the second semiconductor material. In one embodiment, one of the first semiconductor material and the second semiconductor material is a III-V compound semiconductor material, and the other of the first semiconductor material and the second semiconductor material is an elemental semiconductor material or an alloy of at least two elemental semiconductor materials. In this case, etch chemistries known in the art can be employed to etch a III-V compound semiconductor material selective to an elemental semiconductor material or an alloy of at least two elemental semiconductor materials, or to etch an elemental semiconductor material or an alloy of at least two elemental semiconductor materials selective to a III-V compound semiconductor material.

In an illustrative example, the first semiconductor material can be a III-V compound semiconductor material such as InGaAs, and the second semiconductor material can be germanium. In this case, an example of a dry etch process that can be employed to remove the second semiconductor material selective to the first semiconductor material is a reactive ion etch process based on CF₄ and O₂ plasma. Exemplary process conditions for this dry etch process for processing a 300 mm substrate can include a gas flow setting including 100 sccm of CF₄ and 10 sccm of O₂, at a pressure of 300 mTorr, at a temperature of 30° C., and at a radio frequency (RF) input power of about 50 W. An example of a wet etch process that can be employed to remove the second semiconductor material selective to the first semiconductor material is a wet etch employing hydrogen peroxide etch at an elevated temperature of about 30° C. Most III-V compound semiconductor materials including GaAs, AlGaAs, InGaAs, InAlAs, and InP are not etched in hydrogen peroxide, while germanium is etched by hydrogen peroxide.

In another illustrative example, the first semiconductor material can be germanium, and the second semiconductor material can be a III-V compound semiconductor material such as InGaAs. In this case, an example of a wet etch process that can be employed to remove the second semiconductor material selective to the first semiconductor material is a wet etch employing nitric acid (HNO₃). Most III-V compound semiconductor materials are etched in nitric acid while the etch rate of germanium in nitric acid is insignificant. Alternately, buffered oxide etch (BOE) employing hydrofluoric acid may also be employed, which does not remove germanium at any significant etch rate while etching most III-V compound semiconductor materials.

Concurrently with removal of the second semiconductor material between first material first conductivity type nanowires 120N, portions of the second semiconductor material are laterally recessed along the lengthwise direction of the first material first conductivity type nanowires 120N. Thus, each nanowire including a first material first conductivity type nanowires 120N is extended along a lengthwise direction to include a portion of a first material first source region 120S and a portion of a first material first drain region 120D. Portions of p-n junctions are physically exposed around each end portion of a semiconductor nanowire including the first semiconductor material.

If the first semiconductor material and the second semiconductor material are under opposite types of biaxial stress due to lattice mismatch therebetween, a plurality of first material first conductivity type nanowires 120N can be under a first type of strain along a lengthwise direction of the plurality of first material first conductivity type nanowires 120N. The set of semiconductor nanowires including the first material first conductivity type nanowires 120N is herein referred to as first semiconductor nanowires. The first etch-resistant material portion 57 is subsequently removed, for example, by ashing.

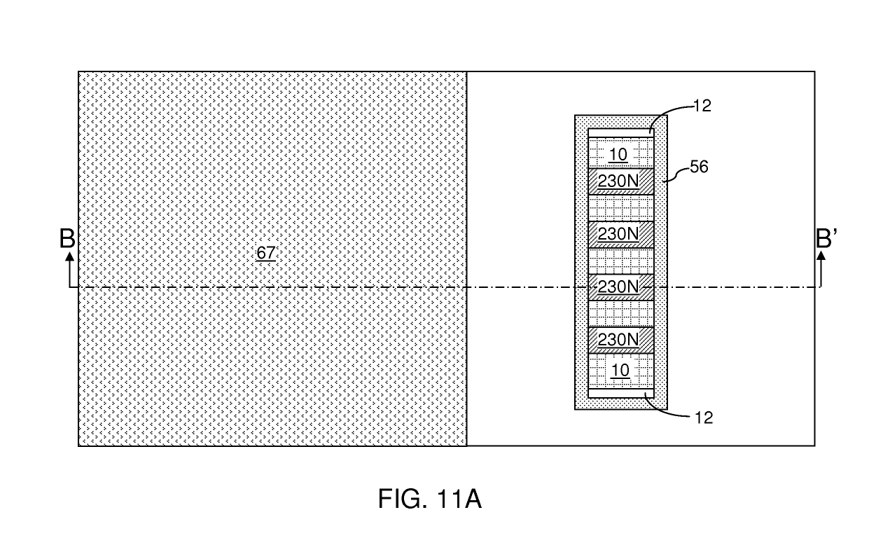

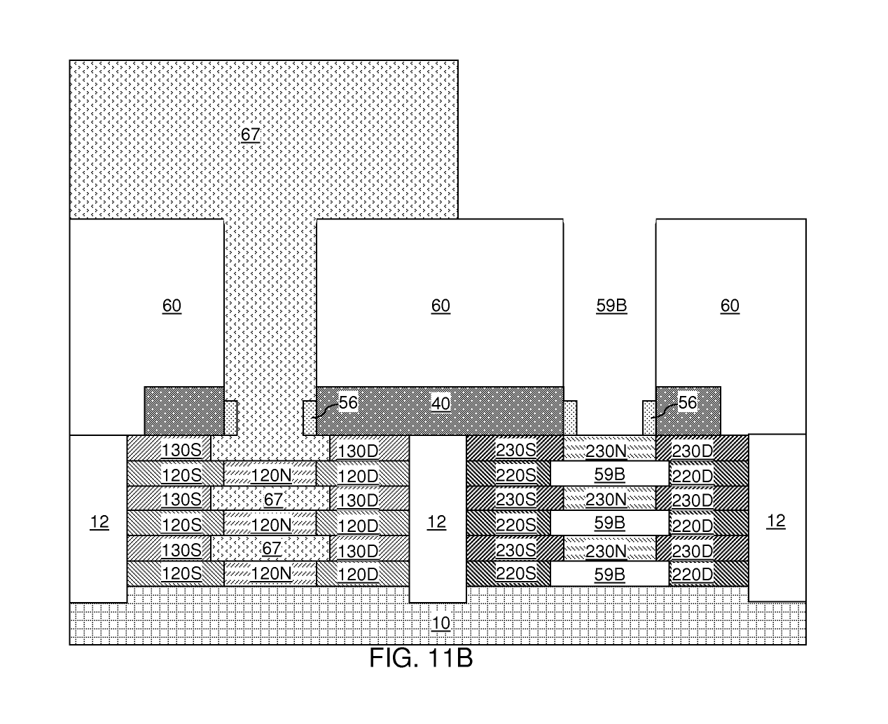

Referring to FIGS. 11A and 11B, a second etch-resistant material portion 67 is formed over the first alternating stack (120S, 130S, 120N, 130N, 120S, 130D), which is a second portion of the alternating stack (20L, 30L; See FIG. 1B). The second etch-resistant material portion 67 is a masking structure that prevents etching of materials in the first alternating stack (120S, 130S, 120N, 130N, 120S, 130D). In one embodiment, the second etch-resistant material portion 67 can be a patterned photoresist material portion, which can be formed by applying a photoresist material over the planarization dielectric layer 60 and within the first and second gate cavities (59A, 59B), and lithographically patterning the photoresist material such that the remaining photoresist material is present over the first alternating stack (120S, 130S, 120N, 130N, 120S, 130D), and is not present over the second alternating stack (220S, 230S, 220N, 230N, 220S, 230D).

A lateral etch of physically exposed portions of the first semiconductor material is performed selective to the second semiconductor material. An isotropic dry etch or an isotropic wet etch can be employed for the lateral etch. Thus, the second gate cavity 59B is laterally expanded by removing the first semiconductor material selective to the second semiconductor material while the second etch-resistant material portion 67 masks the first alternating stack (120S, 130S, 120N, 130N, 120S, 130D). The first material second conductivity type nanowires 220N and physically exposed end sub-portions of the first material first source portions 220S and the first material first drain portions 220D are removed by the lateral etch. The second material second conductivity type nanowires 230N become suspended. The second material second conductivity type nanowires 230N constitute a plurality of second suspended semiconductor nanowires, includes the second semiconductor material, and are located underneath the second gate cavity 59B as formed at the processing step of FIGS. 6A, 6B, and 6C.

The etch chemistry for the isotropic selective etch can be optimized for the combination of the second semiconductor material and the first semiconductor material. Etch chemistries described above can be employed to selectively etch a III-V compound semiconductor material without etching an elemental semiconductor material or an alloy of at least two elemental semiconductor materials.

Concurrently with removal of the first semiconductor material between second material second conductivity type nanowires 230N, portions of the first semiconductor material are laterally recessed along the lengthwise direction of the second material second conductivity type nanowires 230N. Thus, each nanowire including a second material second conductivity type nanowires 230N is extended along a lengthwise direction to include a portion of a second material second source region 230S and a portion of a second material second drain region 230D. Portions of p-n junctions are physically exposed around each end portion of a semiconductor nanowire including the second semiconductor material.

If the second semiconductor material and the first semiconductor material are under opposite types of biaxial stress due to lattice mismatch therebetween, a plurality of second material second conductivity type nanowires 230N can be under a second type of strain along a lengthwise direction of the plurality of second material second conductivity type nanowires 230N. The second type of strain is the opposite type of the first type of strain. For example, the first type of strain can be a tensile strain and the second type of strain can be a compressive strain, or vice versa. The set of semiconductor nanowires including the second material second conductivity type nanowires 230N is herein referred to as second semiconductor nanowires.

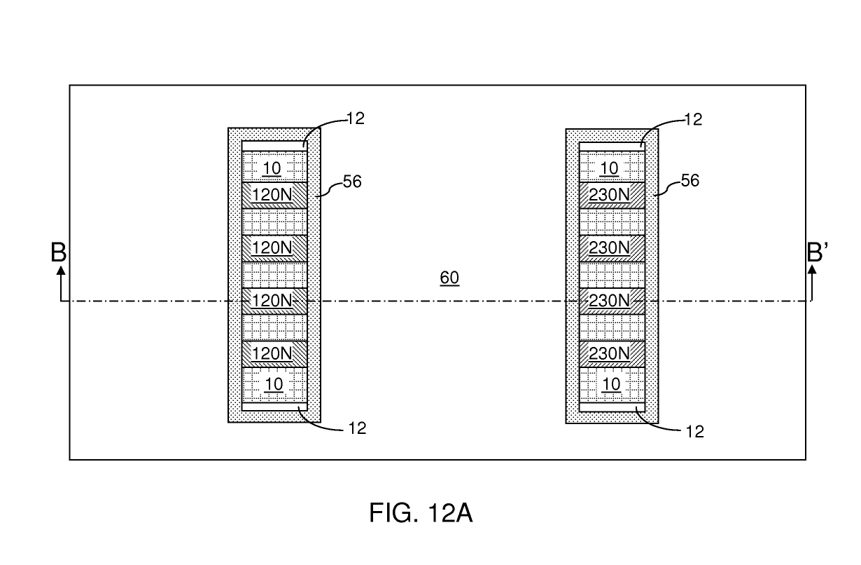

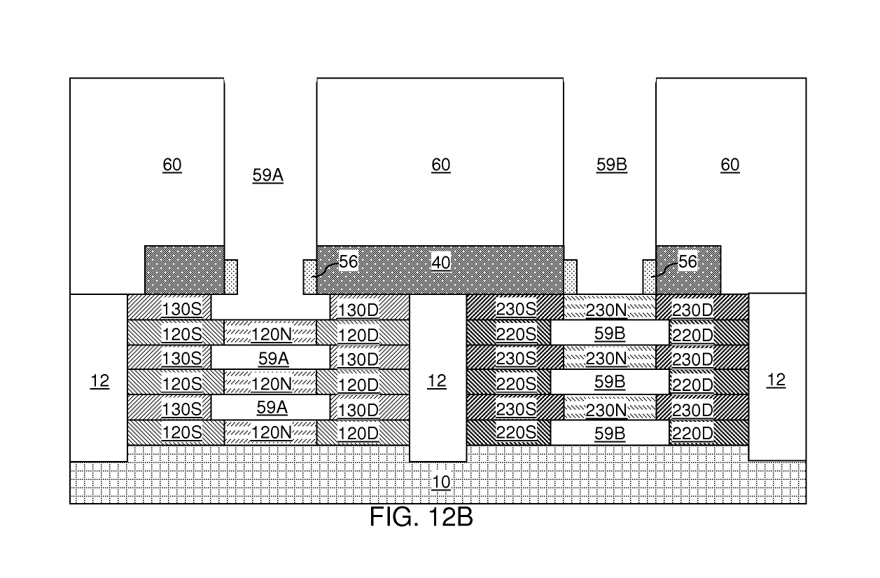

Referring to FIGS. 12A and 12B, the second etch-resistant material portion 67 is subsequently removed, for example, by ashing.

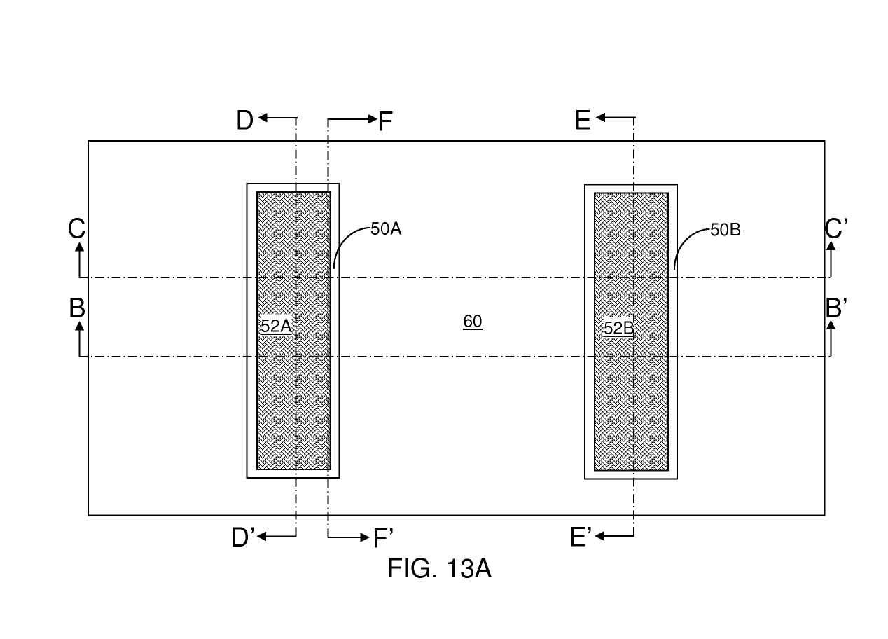

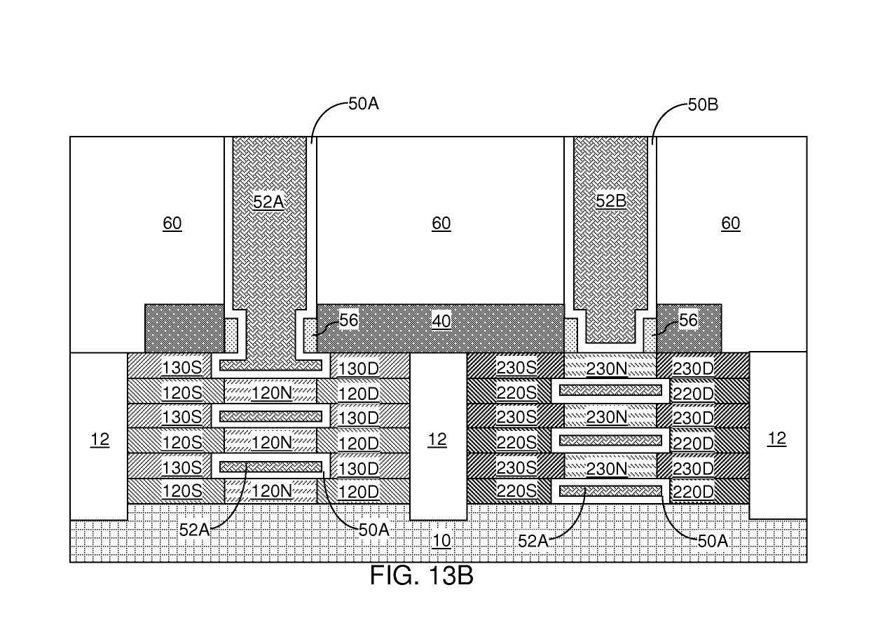

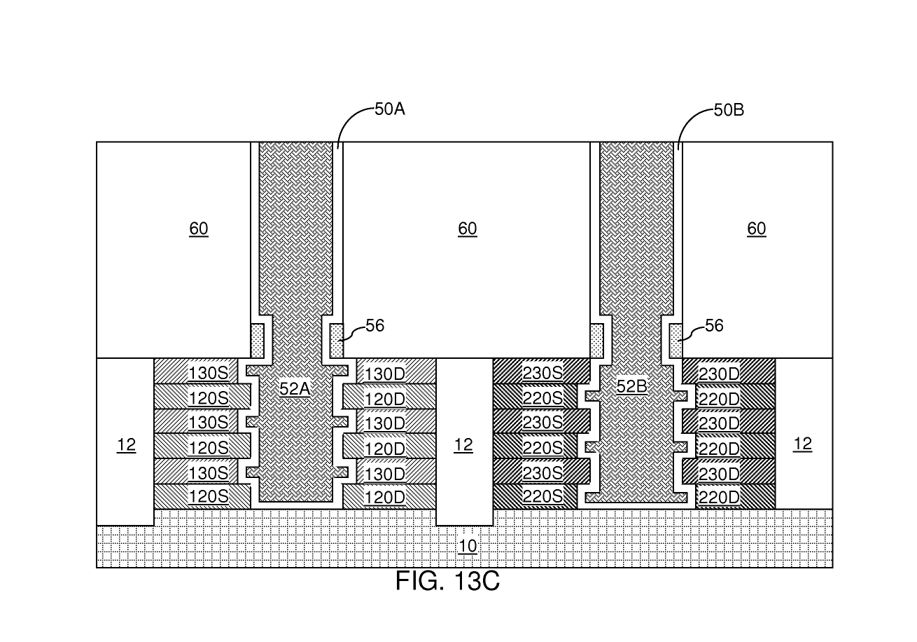

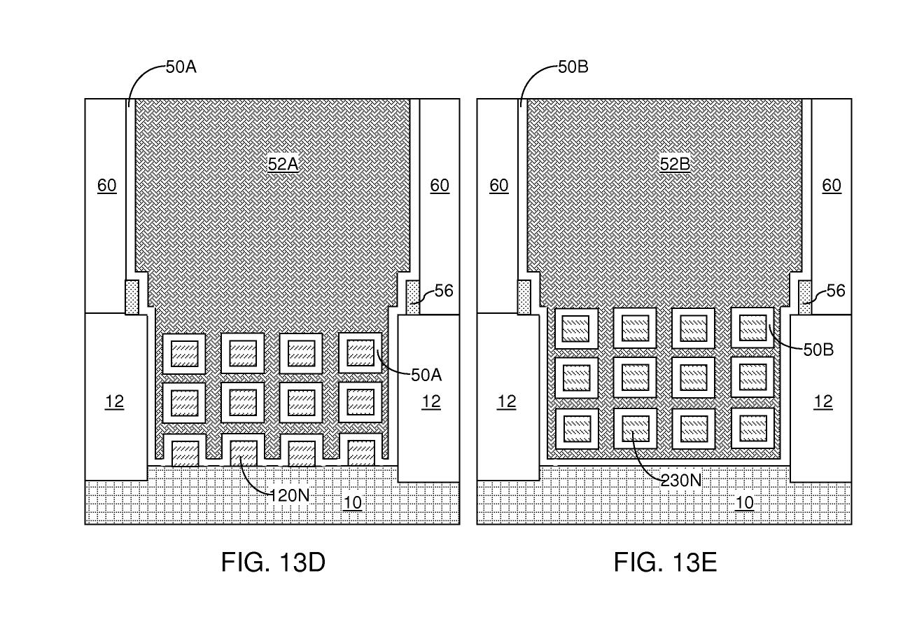

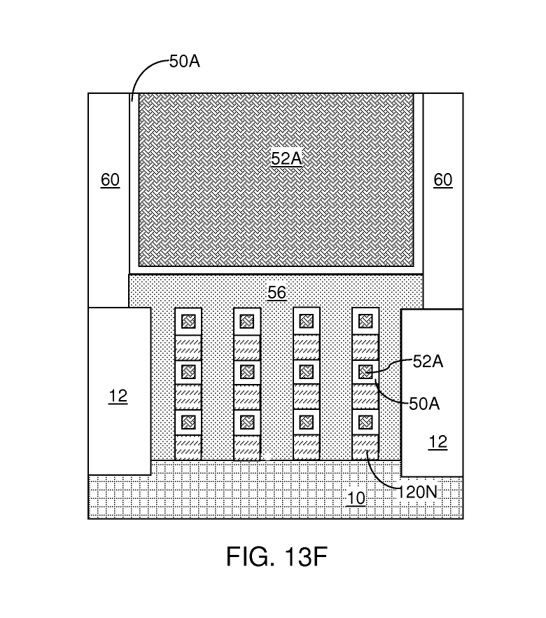

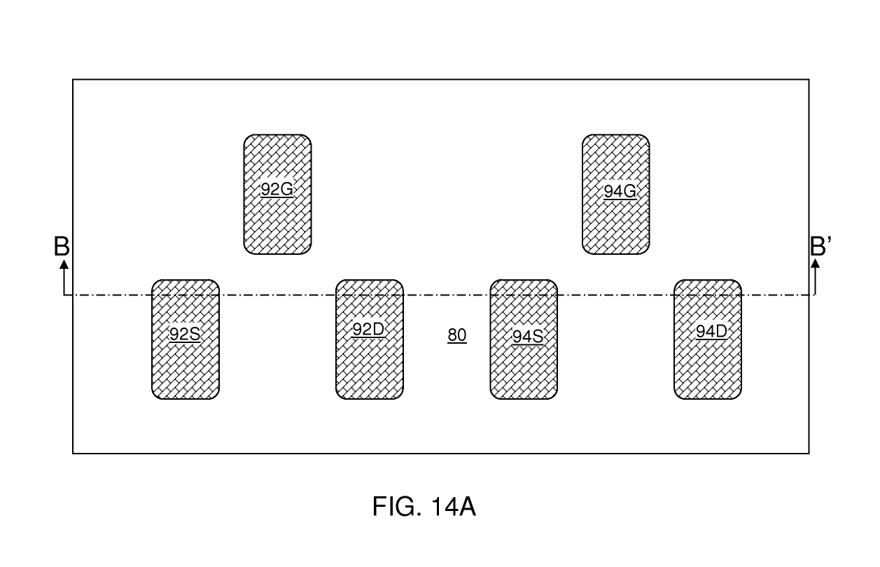

Referring to FIGS. 13A, 13B, 13C, 13D, 13E, and 13F, gate dielectrics (50A, 50B) and gate electrodes (52A, 52B) are formed within the gate cavities (59A, 59B). The gate dielectrics (50A, 50B) include a first contiguous gate dielectric 50A and a second contiguous gate dielectric 50B. The gate electrodes (52A, 52B) include a first gate electrode 52A and a second gate electrode 52B. The first and second contiguous gate dielectrics (50A, 50B) and the first and second gate electrodes (52A, 52B) are formed by depositing a stack of a gate dielectric layer and a gate conductor layer within the first and second gate cavities (59A, 59B) and removing portions of the gate dielectric layer and the gate conductor layer from above a top surface of the planarization dielectric layer 60.

Specifically, a gate dielectric layer can be deposited on physically exposed surfaces within the gate cavities (59A, 59B) and on the top surface of the planarization dielectric layer. The gate dielectric layer can include any gate dielectric material known in the art. Subsequently, a conductive material is deposited into the first gate cavity 59A and the second gate cavity 59B. The conductive material, and optionally, the gate dielectric layer are subsequently planarized, for example, by chemical mechanical planarization (CMP). The remaining portion of the gate dielectric layer filling the first gate cavity 59A constitutes the first contiguous gate dielectric 50A, which is contiguous throughout the entirety thereof. The remaining portion of the gate dielectric layer filling the second gate cavity 59B constitutes the second contiguous gate dielectric 50B, which is contiguous throughout the entirety thereof. The remaining portion of the conductive material filling the first gate cavity 59A constitutes the first gate electrode 52A. The remaining portion of the conductive material filling the second gate cavity 59B constitutes the second gate electrode 52B.

The first contiguous gate dielectric 50A is formed on all physically exposed surfaces of the plurality of first semiconductor wires that include first material first conductivity type nanowires 120N. The second contiguous gate dielectric 50B is formed on all physically exposed surfaces of the plurality of second semiconductor wires that includes second material second conductivity type nanowires 230N. The first gate electrode 52A is formed on the first contiguous gate dielectric 50A and within the first gate cavity 59A. The second gate electrode 52B is formed on the second contiguous gate dielectric and within the second gate cavity 59B.

The first alternating stack, which is a first portion of the alternating stack (20L, 30L; See FIG. 1B), includes various sub-portions. The various sub-portions of the first alternating stack include the first source region (120S, 130S) including a first portion of the alternating stack (20L, 30L), and the first drain region (120D, 130D) including a second portion of the alternating stack (20L, 30L). The second alternating stack, which is a second portion of the alternating stack (20L, 30L; See FIG. 1B), includes various sub-portions. The various sub-portions of the second alternating stack include the second source region (220S, 230S) including a third portion of the alternating stack (20L, 30L), and the second drain region (220D, 230D) including a fourth portion of the alternating stack (20L, 30L).

The exemplary semiconductor structure includes a first field effect transistor and a second field effect transistor. The first transistor includes the first source region (120S, 130S) including a first alternating stack of a first semiconductor material and a second semiconductor material that is different from the first semiconductor material; a first drain region (120D, 130D) including a second alternating stack of the first semiconductor material and the second semiconductor material; a plurality of first channels located within a plurality of first semiconductor nanowires including the first semiconductor material, i.e., the plurality of first material first conductivity type nanowires 120N, and extending between the first source region (120S, 130S) and the first drain region (120D, 130D); and a first gate electrode 52A surrounding each of the first plurality of semiconductor nanowires. The second transistor includes a second source region (220S, 230S) including a third alternating stack of the first semiconductor material and the second semiconductor material; a second drain region (220D, 230D) including a fourth alternating stack of the first semiconductor material and the second semiconductor material; a plurality of second channels located within a plurality of second semiconductor nanowires including the second semiconductor material, i.e., the plurality of second material second conductivity type nanowires 230N, and extending between the second source region (220S, 230S) and the second drain region (220D, 230D); and a second gate electrode 52B surrounding each of the second plurality of semiconductor nanowires.

The first source region (120S, 130S), the first drain region (120D, 130D), the second source region (220S, 230S), and the second drain region (220D, 230D) are located on the top surface of the single crystalline substrate layer 10, and have an identical sequence of semiconductor materials from bottom to top, and each semiconductor material layer within the identical sequence is located at a same distance from the top surface across the first source region (120S, 130S), the first drain region (120D, 130D), the second source region (220S, 230S), and the second drain region (220D, 230D). In one embodiment, the first alternating stack, the second alternating stack, the third alternating stack, and the fourth alternating stack includes at least two repetitions of the first semiconductor material and the second semiconductor material.

The first source region (120S, 130S) can include first end portions of the plurality of first semiconductor nanowires, and the first drain region (120D, 130D) can include second end portions of the plurality of first semiconductor nanowires. The second source region (220S, 230S) can include first end portions of the plurality of second semiconductor nanowires, and the second drain region (220D, 230D) can include second end portions of the plurality of second semiconductor nanowires.

The first source region (120S, 130S), the first drain region (120D, 130D), the second source region (220S, 230S), and the second drain region (220D, 230D) are in contact with the single crystalline substrate layer 10. The first drain region (120D, 130D), the second source region (220S, 230S), and the second drain region (220D, 230D) can be epitaxially aligned to the single crystalline substrate layer 10.

One of the first semiconductor material and the second semiconductor material can have a lattice constant that is greater than a lattice constant of the single crystalline substrate layer 10, and another of the first semiconductor material and the second semiconductor material can have another lattice constant that is less than the lattice constant of the single crystalline substrate layer 10. The plurality of first semiconductor nanowires can be under a first type of strain along a lengthwise direction of the plurality of first semiconductor nanowires, and the plurality of second semiconductor nanowires is under a second type of strain along a lengthwise direction of the plurality of second semiconductor nanowires. One of the first type and the second type is compressive, and another of the first type and the second type is tensile.

In one embodiment, one of the first and second field effect transistors can be a p-type field effect transistor, and another of the first and second field effect transistors can be an n-type field effect transistor.

A first gate spacer 56 (i.e., the gate spacer 56 in contact with the first contiguous gate dielectric 50A) includes a dielectric material and contacts sidewalls of the first source region (120S, 130S) and sidewalls of the first drain region (120D, 130D). A second gate spacer 56 (i.e., the gate spacer 56 in contact with the second contiguous gate dielectric 50B) includes the same dielectric material and contacts sidewalls of the second source region (220S, 230S) and sidewalls of the second drain region (220D, 230D). The first gate spacer 56 includes at least one vertical strip (as illustrated in FIG. 9C) having a uniform width and contacting sidewalls of at least two of the plurality of first semiconductor nanowires. The second gate spacer 56 includes at least one vertical strip (as illustrated in FIG. 9C) having the uniform width and contacting sidewalls of at least two of the plurality of second semiconductor nanowires. The first and second gate spacers 56 can be in contact with the single crystalline substrate layer 10.

The planarization dielectric layer 60 is located over the first source region (120S, 130S), the first drain region (120D, 130D), the second source region (220S, 230S), and the second drain region (220D, 230D) and contacts sidewalls of the first and second gate spacers 56. A top surface of the first gate electrode 52A and a top surface of the second gate electrode 52B can be coplanar with the top surface of the planarization dielectric layer 60.

The first gate electrode 52A includes a plurality of portions that laterally extend underneath the first gate spacer 56 along a lengthwise direction of the plurality of first semiconductor fins. The second gate electrode 52B includes a plurality of portions that laterally extend underneath the second gate spacer 56 along a lengthwise direction of the plurality of second semiconductor fins. The first contiguous gate dielectric 50A contacts the first gate electrode 52A, and the second contiguous gate dielectric 50B contacts the second gate electrode 52B. One of the first contiguous gate dielectric 50A and the second contiguous gate dielectric 50B contacts one of a bottom surface of the first gate spacer 56 and a bottom surface of the second gate spacer 56, i.e., a bottom space of portions of the gate spacers 56 illustrated in FIG. 13C.

The first source region (120S, 130S), the first drain region (120D, 130D), and the first contiguous gate dielectric 50A contact all surfaces of the plurality of first channels included within the first material first conductivity type nanowires 120N. The second source region (220S, 230S), the second drain region (220D, 230D), and the second contiguous gate dielectric 50B contact all surfaces of the plurality of second channels included within the second material second conductivity type nanowires 230N. The single crystalline substrate layer 10 is in contact with the first source region (120S, 130S), the first drain region (120D, 130D), the second source region (220S, 230S), the second drain region (220D, 230D), the first contiguous gate dielectric 52A, and the second contiguous gate dielectric 52B.

The plurality of first semiconductor nanowires can be a first two-dimensional array of semiconductor nanowires, and the plurality of second semiconductor nanowires can be a second two-dimensional array of semiconductor nanowires. The semiconductor nanowires within the first two-dimensional array of semiconductor nanowires are vertically spaced and laterally spaced along a horizontal direction perpendicular to a lengthwise direction of the plurality of first semiconductor nanowires, and semiconductor nanowires within the second two-dimensional array of semiconductor nanowires are vertically spaced and laterally spaced along a horizontal direction perpendicular to a lengthwise direction of the plurality of second semiconductor nanowires. In one embodiment, each of the first two-dimensional array of semiconductor nanowires and the first two-dimensional array of semiconductor nanowires is a two-dimensional periodic array having a first periodicity along a vertical direction and a second periodicity along a horizontal direction. The first periodicity is the center-to-center distance between a vertically neighboring pair of semiconductor nanowires, and the second periodicity is the center-to-center distance between a laterally neighboring pair of semiconductor nanowires.

While an embodiment in which the first and second disposable gate structures (51A, 51B) are simultaneously removed is described herein, a variation is expressly contemplated herein in which the first disposable gate structure 51A and the second disposable gate structure 51B are removed at different processing steps. For example, only one of the first and second disposable gate structures (51A, 51B) may be removed by masking the other of the first and second disposable gate structures (51A, 51B) with a mask material layer at a processing step of FIGS. 6A, 6B, and 6C. Processing steps of FIGS. 7A, 7B, and 7C, FIGS. 8A and 8B, and FIGS. 9A, 9B, and 9C can be subsequently performed within a gate cavity (59A or 59B). Either the processing steps of FIGS. 10A and 10B or the processing steps of FIGS. 11A and 11B can be performed without use of any etch-resistant material portion if the remaining disposable gate structures (51A or 51B) can function as an etch-resistant material portion. The processing steps of FIGS. 12A and 12B and the processing steps of FIGS. 13A-13F can then be performed. Subsequently, the remaining disposable gate structure (51A or 51B) can be removed selective to a gate dielectric (50A or 50B) and a gate electrode (52A or 52B) or employing a masking layer (not shown) that covers the gate dielectric (50A or 50B) and the gate electrode (52A or 52B). Processing steps of FIGS. 7A, 7B, and 7C, FIGS. 8A and 8B, and FIGS. 9A, 9B, and 9C can be subsequently performed in the gate cavity (59A or 59B) that is formed by removal of the remaining disposable gate structure (51B or 51A). Either the processing steps of FIGS. 10A and 10B or the processing steps of FIGS. 11A and 11B can be performed without use of any etch-resistant material portion if the replacement gate structure ((50A, 52A) or (50B, 52B)) or the masking layer can function as an etch-resistant material portion. The processing steps of FIGS. 12A and 12B and the processing steps of FIGS. 13A-13F can then be performed. The masking layer, if present, can be removed at a suitable processing step.

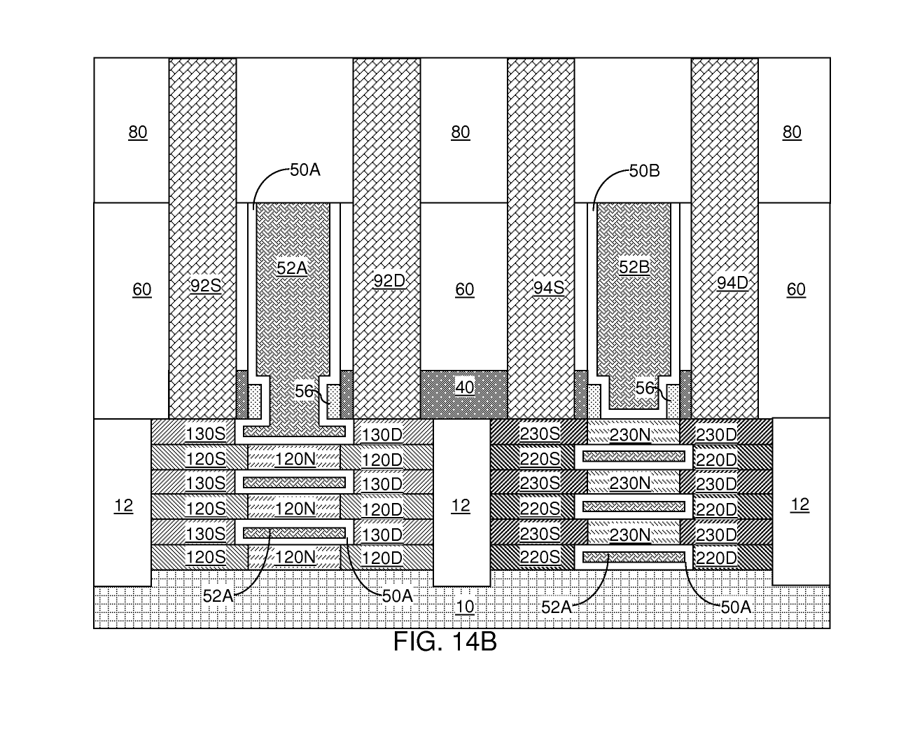

Referring to FIGS. 14A and 14B, a contact level dielectric layer 80 can be formed over the planarization dielectric layer 60. The contact level dielectric layer 80 includes a dielectric material such as silicon oxide, silicon nitride, silicon oxynitride, organosilicate, or combinations of thereof. A first source contact structure 92S, a first drain contact structure 92D, a first gate contact structure 92G, a second source contact structure 94S, a second drain contact structure 94D, and a second gate contact structure 94G can be formed through the contact level dielectric layer 80 to provide electrical contact to the first source region (120S, 130S), the first drain region (120D, 130D), the first gate electrode 52A, the second source region (220S, 230S), the second drain region (220D, 230D), and the second gate electrode 52B, respectively.

The methods of embodiments of the present disclosure can provide two types of nanomesh structures, i.e., a two-dimensional array of nanowires, including two different types of semiconductor materials, i.e., the first semiconductor material and the second semiconductor material. The two types of nanomesh structures are collectively referred to as hybrid nanomesh structures. The two different types of semiconductor materials can be selected to independently optimize device performance of p-type field effect transistors including a nanomesh structure of semiconductor nanowires of one of the two semiconductor materials, and n-type field effect transistors including a nanomesh structure of semiconductor nanowires of the other of the two semiconductor materials. Further, the nanomesh structures enable vertical stacking of semiconductor nanowires, and consequent increase of on-current per unit device area.

While the disclosure has been described in terms of specific embodiments, it is evident in view of the foregoing description that numerous alternatives, modifications and variations will be apparent to those skilled in the art. Each of the embodiments described herein can be implemented individually or in combination with any other embodiment unless expressly stated otherwise or clearly incompatible. Accordingly, the disclosure is intended to encompass all such alternatives, modifications and variations which fall within the scope and spirit of the disclosure and the following claims.

What is claimed is:

1. A method of forming a semiconductor structure comprising:
forming an alternating stack of a first semiconductor material and a second semiconductor material that is different from said first semiconductor material on a single crystalline substrate layer;
forming a planarization dielectric layer including a first gate cavity and a second gate cavity over said alternating stack;
forming a plurality of first semiconductor nanowires comprising said first semiconductor material underneath said first gate cavity by patterning a first portion of said alternating stack; and
forming a plurality of second semiconductor nanowires comprising said second semiconductor material underneath said second gate cavity by patterning a second portion of said alternating stack.

2. The method of claim 1, further comprising:
forming a plurality of fin-defining mask structures over said alternating stack prior to forming said planarization dielectric layer; and
extending said first gate cavity and said second gate cavity downward by etching said alternating stack employing a combination of said planarization dielectric layer and said plurality of fin-defining mask structures as an etch mask.

3. The method of claim 2, wherein said patterning of said first portion of said alternating stack comprises laterally expanding said first gate cavity by removing said second semiconductor material selective to said first semiconductor material while an etch-resistant material portion masks said second portion of said alternating stack.

4. The method of claim 3, wherein said lateral expansion of said first gate cavity is performed by an isotropic etch, and said etch-resistant material portion is a photoresist portion.

5. The method of claim 1, further comprising:
forming a first disposable gate structure over said first portion of said alternating stack and a second disposable gate structure over said second portion of said alternating stack;
depositing and planarizing a dielectric material over said first and second disposable gate structures; and
removing said first and second disposable gate structures selective to said deposited and planarized dielectric material, wherein said deposited and planarized dielectric material constitutes said planarization dielectric layer including said first gate cavity and said second gate cavity.

6. The method of claim 5, further comprising:
forming a plurality of fin-defining mask structures over said alternating stack, wherein said first and second disposable gate structures are formed over said plurality of fin-defining mask structures; and
extending said first gate cavity and said second gate cavity downward by etching said alternating stack employing a combination of said planarization dielectric layer and said plurality of fin-defining mask structures as an etch mask.

7. The method of claim 1, further comprising:
providing a dopant of a first conductivity type to said first portion of said alternating stack prior to said forming of said planarization dielectric layer; and
providing a dopant of a second conductivity type that is the opposite of said first conductivity type to said second portion of said alternating stack.

8. The method of claim 7, further comprising:
forming a first disposable gate structure over said first portion of said alternating stack and a second disposable gate structure over said second portion of said alternating stack;
doping sub-portions of said first portion of said alternating stack with dopants of said second conductivity type employing said first disposable gate structure as an implantation mask; and
doping sub-portions of said second portion of said alternating stack with dopants of said first conductivity type employing said second disposable gate structure as an implantation mask.

9. The method of claim 1, wherein an entirety of said alternating stack is epitaxially aligned to said single crystalline substrate layer upon formation.

10. The method of claim 9, wherein one of said first semiconductor material and said second semiconductor material has a lattice constant that is greater than a lattice constant of said single crystalline substrate layer, and another of said first semiconductor material and said second semiconductor material has another lattice constant that is less than said lattice constant of said single crystalline substrate layer.

11. The method of claim 1, further comprising:
vertically extending said first gate cavity down to a top surface of said single crystalline substrate layer; and
vertically extending said second gate cavity down to said top surface of said single crystalline substrate layer.

12. The method of claim 11, further comprising forming a plurality of fin-defining mask structures over said alternating stack prior to forming said planarization dielectric layer, wherein said first gate cavity and said second gate cavity are vertically extended only within regions that are not blocked by said plurality of fin-defining mask structures.

13. The method of claim 1, further comprising:
forming a first contiguous gate dielectric on all physically exposed surfaces of said plurality of first semiconductor wires; and
forming a second contiguous gate dielectric on all physically exposed surfaces of said plurality of second semiconductor wires.

14. A semiconductor structure comprising a first field effect transistor and a second field effect transistor,
wherein said first field effect transistor comprises:
a first source region comprising a first alternating stack of a first semiconductor material and a second semiconductor material that is different from said first semiconductor material;
a first drain region comprising a second alternating stack of said first semiconductor material and said second semiconductor material;
a plurality of first channels located within a plurality of first semiconductor nanowires comprising said first semiconductor material and extending between said first source region and said first drain region; and
a first gate electrode surrounding each of said first plurality of semiconductor nanowires, and wherein said second field effect transistor comprises:
a second source region comprising a third alternating stack of said first semiconductor material and said second semiconductor material;
a second drain region comprising a fourth alternating stack of said first semiconductor material and said second semiconductor material;
a plurality of second channels located within a plurality of second semiconductor nanowires comprising said second semiconductor material and extending between said second source region and said second drain region; and
a second gate electrode surrounding each of said second plurality of semiconductor nanowires.

15. The semiconductor structure of claim 14, wherein said first source region, said first drain region, said second source region, and said second drain region are in contact with a single crystalline substrate layer.

16. The semiconductor structure of claim 15, wherein said first source region, said first drain region, said second source region, and said second drain region are epitaxially aligned to said single crystalline substrate layer.

17. The semiconductor structure of claim 16, wherein one of said first semiconductor material and said second semiconductor material has a lattice constant that is greater than a lattice constant of said single crystalline substrate layer, and another of said first semiconductor material and said second semiconductor material has another lattice constant that is less than said lattice constant of said single crystalline substrate layer.

18. The semiconductor structure of claim 15, wherein said single crystalline substrate layer comprises an intrinsic semiconductor material.

19. The semiconductor structure of claim 14, wherein said first source region comprises first end portions of said plurality of first semiconductor nanowires, said first drain region comprises second end portions of said plurality of first semiconductor nanowires, said second source region comprises first end portions of said plurality of second semiconductor nanowires, and said second drain region comprises second end portions of said plurality of second semiconductor nanowires.

20. The semiconductor structure of claim 19, further comprising:
a first gate spacer comprising a dielectric material and contacting a sidewall of said first source region and a sidewall of said first drain region; and
a second gate spacer comprising said dielectric material and contacting a sidewall of said second source region and a sidewall of said second drain region.

21. The semiconductor structure of claim 20, wherein said first gate spacer comprises at least one vertical strip having a uniform width and contacting sidewalls of at least two of said plurality of first semiconductor nanowires, and said second gate spacer comprises at least one vertical strip having said uniform width and contacting sidewalls of at least two of said plurality of second semiconductor nanowires.

22. The semiconductor structure of claim 20, further comprising a planarization dielectric layer located over said first source region, said first drain region, said second source region, and said second drain region and contacting sidewalls of said first and second gate spacers.

23. The semiconductor structure of claim 20, wherein said first gate electrode includes a plurality of portions that laterally extend underneath said first gate spacer along a lengthwise direction of said plurality of first semiconductor fins, and said second gate electrode includes a plurality of portions that laterally extend underneath said second gate spacer along a lengthwise direction of said plurality of second semiconductor fins.

24. The semiconductor structure of claim 14, further comprising a first contiguous gate dielectric and a second contiguous gate dielectric, wherein said first source region, said first drain region, and said first contiguous gate dielectric contact all surfaces of said plurality of first channels, and said second source region, said second drain region, and said second contiguous gate dielectric contact all surfaces of said plurality of second channels.

25. The semiconductor structure of claim 14, wherein said first source region, said first drain region, said second source region, and said second drain region are located on a single crystalline substrate layer having a top surface, and have an identical sequence of semiconductor materials from bottom to top, and each semiconductor material layer within said identical sequence is located at a same distance from said top surface across said first source region, said first drain region, said second source region, and said second drain region.
